(19) United States
(12) Patent Application Publication
(10) Pub. No.: US 2024/0126175 A1
(43) Pub. Date: Apr. 18, 2024

(54) METHOD FOR FORMING RESIST PATTERN, METHOD FOR PRODUCING SEMICONDUCTOR DEVICE, SUBSTRATE PROCESSING DEVICE, AND STORAGE MEDIUM

(71) Applicant: Tokyo Electron Limited, Tokyo (JP)

(72) Inventors: Seiji NAGAHARA, Tokyo (JP); Congque DINH, Koshi City (JP); Makoto MURAMATSU, Koshi City (JP); Kayoko CHO, Koshi City (JP)

(21) Appl. No.: 18/470,491

(22) Filed: Sep. 20, 2023

Related U.S. Application Data
(63) Continuation-in-part of application No. PCT/JP2022/034283, filed on Sep. 13, 2022.

(30) Foreign Application Priority Data
Sep. 27, 2021 (JP) 2021-156963

(51) Int. Cl. G03F 7/40

(52) U.S. Cl. CPC G03F 7/40; G03F 7/11

(57) ABSTRACT

Disclosed is a method for forming a resist pattern including, in the following order, irradiating a part of a resist film containing a resist material with a first radiation, baking the resist film, irradiating the entire region including the part irradiated with the first radiation and other parts in the resist film with a second radiation in a batch, and forming a resist pattern by development for removing a part of the resist film.

### CROSS-REFERENCE TO RELATED APPLICATIONS

This application is a continuation-in-part of International Patent Application No. PCT/JP2022/034283, filed on Sep. 13, 2022, which claims the benefit of the priority from Japanese Patent Application No. 2021-156963 filed on Sep. 27, 2021. The entire contents of the above listed International Patent Application and priority application are incorporated herein by reference.

### BACKGROUND

The present disclosure relates to a method for forming a resist pattern, a method for producing a semiconductor device, a substrate processing device, and a storage medium.

Conventionally, an extreme ultraviolet (EUV) lithography technique with a chemically amplified resist material has been used to form a fine resist pattern having a size of 20 nm (Japanese Unexamined Patent Publication No. 2020-101593). In the case of chemically amplified resist material, generally, the reaction for forming a resist pattern proceeds by the action of an acid catalyst generated by pattern exposure. It has been proposed to use a non-chemically amplified resist material to form a fine resist pattern by EUV lithography (US Patent Application Publication No. 2020/0064733 and J. Micro/Nanolith. MEMS MOEMS 16(2), 023510 (April-June 2017)).

### SUMMARY

In forming a fine resist pattern, further reduction of the roughness of the resist pattern is desired.

One aspect of the present disclosure relates to a method for forming a resist pattern including, in the following order, irradiating a part of a resist film containing a resist material with a first radiation, baking the resist film, irradiating an entire region including the part irradiated with the first radiation and other parts in the resist film with a second radiation in a batch, and forming a resist pattern by development for removing a part of the resist film. The first radiation is ionizing radiation or non-ionizing radiation, the second radiation is non-ionizing radiation, and in a case where the first radiation is non-ionizing radiation, the second radiation is non-ionizing radiation having a wavelength longer than a wavelength of the first radiation.

With the method according to the present disclosure, it is possible to reduce the roughness of a fine resist pattern formed by extreme ultraviolet (EUV) lithography or the like. With the method according to the present disclosure, it is possible to form a fine resist pattern formed by extreme ultraviolet (EUV) lithography with high contrast.

### BRIEF DESCRIPTION OF THE DRAWINGS

FIG. 1 is a flowchart illustrating an example of a method for forming a resist pattern.

FIG. 2A is a process chart illustrating an example of a method for producing a semiconductor device by a method including forming a resist pattern.

FIG. 2B is a process chart illustrating an example of a method for producing a semiconductor device by a method including forming a resist pattern.

FIG. 2C is a process chart illustrating an example of a method for producing a semiconductor device by a method including forming a resist pattern.

FIG. 3A is a process chart illustrating an example of a method for producing a semiconductor device by a method including forming a resist pattern.

FIG. 3B is a process chart illustrating an example of a method for producing a semiconductor device by a method including forming a resist pattern.

FIG. 4A is a process chart illustrating an example of a method for producing a semiconductor device by a method including forming a resist pattern.

FIG. 4B is a process chart illustrating an example of a method for producing a semiconductor device by a method including forming a resist pattern.

FIG. 4C is a process chart illustrating an example of a method for producing a semiconductor device by a method including forming a resist pattern.

FIG. 5 is a flowchart illustrating an example of a method for forming a resist pattern.

FIG. 6 is a flowchart illustrating an example of a method for forming a resist pattern.

FIG. 7 is a schematic view illustrating an example of a substrate processing device.

FIG. 8 is a schematic view illustrating an example of a substrate processing device.

FIG. 9 is a schematic view illustrating an example of an exposure unit.

FIG. 10 is a graph illustrating a relationship between the thickness of a resist film remaining after a development process and EUV dose.

FIG. 11 is a graph illustrating a relationship between the thickness of a resist film remaining after a development process and EUV dose.

FIG. 12 is a graph illustrating a relationship between the thickness of a resist film remaining after a development process and EUV dose.

FIG. 13 is a graph illustrating a relationship between a critical dimension (CD) of a resist pattern and EUV dose.

FIG. 14 is a graph illustrating a relationship between a line width roughness (LWR) and a critical dimension (CD) of a resist pattern.

FIG. 15 is a graph illustrating a relationship between the number of defects and a critical dimension (CD) of a resist pattern.

FIG. 16 is a graph illustrating a relationship between a critical dimension (CD) of a resist pattern and EUV dose.

FIG. 17 is a graph illustrating a relationship between the thickness of a resist film remaining after a development process and dose of a KrF excimer laser.

FIG. 18 is a diagram illustrating an example of the hardware configuration of a control device 100 according to an embodiment of the present disclosure.

### DETAILED DESCRIPTION

Hereinafter, embodiments according to the present disclosure will be described as examples for explaining the present invention. However, the present invention is not limited to what will be described below. In the following description, in some cases, the same components or the components having the same functions will be represented by the same reference numerals to avoid redundant description.

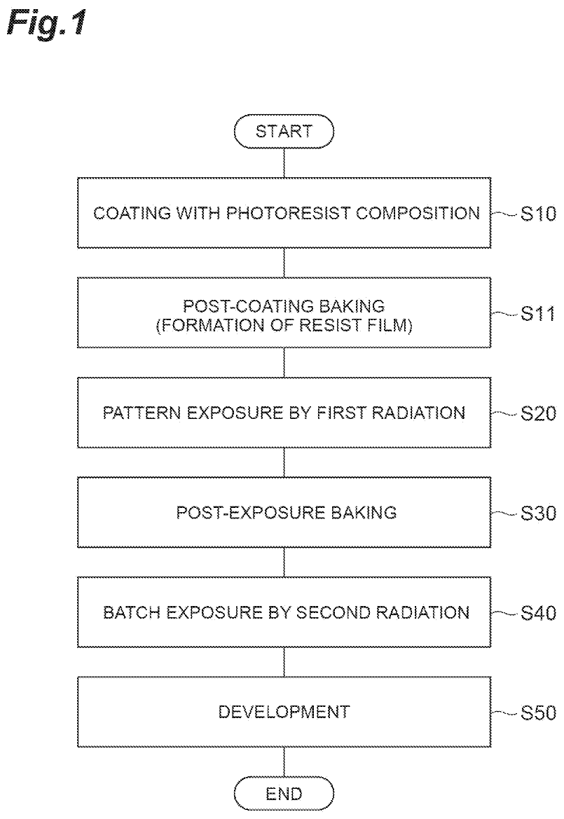

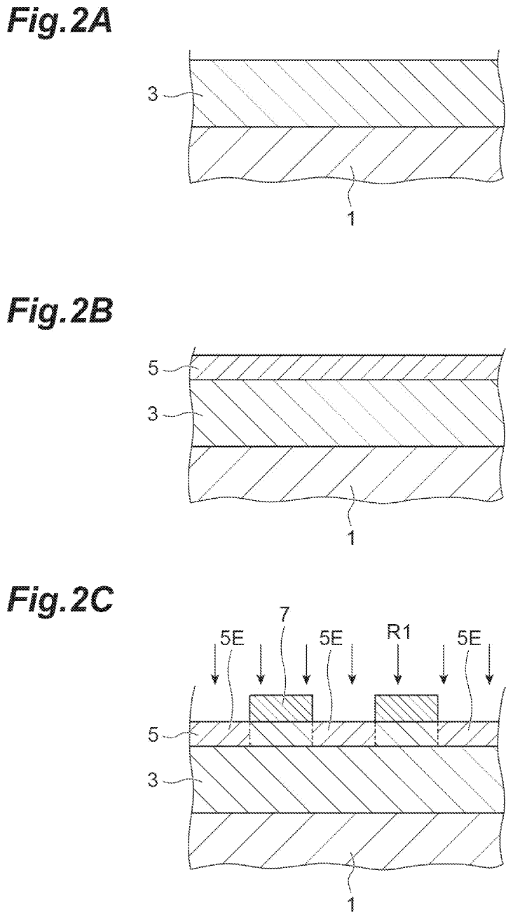

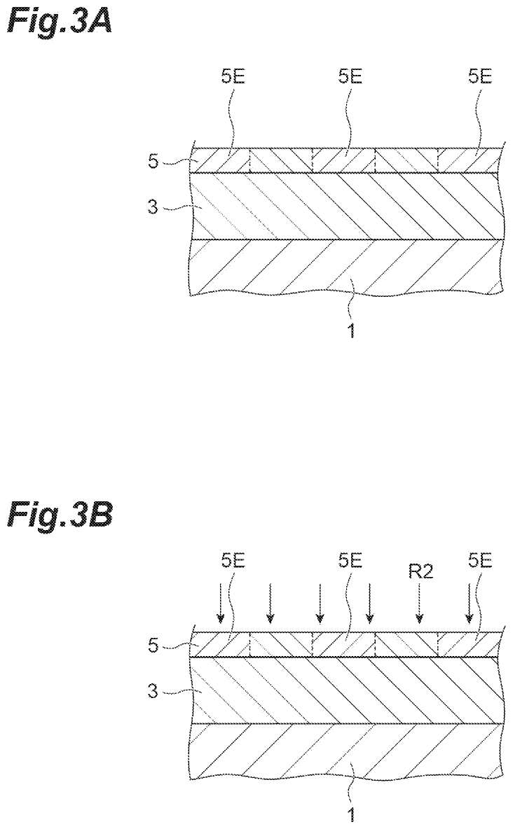

FIG. 1 is a flowchart illustrating an example of a method for forming a resist pattern. FIGS. 2A, 2B, 2C, 3A, 3B, 4A, 4B, and 4C are process charts illustrating an example of a method for forming a resist pattern and a method for producing a semiconductor device including forming a resist pattern by the method.

The method for forming a resist pattern illustrated in FIGS. 1A to 4C include, in the following order, a step S10 of coating an underlayer film 3 (etching target film) provided on a semiconductor wafer 1 with a photoresist composition, a step S11 of forming a resist film 5 by baking the photoresist composition with which the underlayer film 3 is coated, a step S20 as pattern exposure of irradiating a part (5E) of the resist film 5 with a first radiation R1, a step S30 as post-exposure baking of baking the resist film 5 having undergone the pattern exposure, a step S40 as batch exposure of irradiating the entire region including the part 5E irradiated with the first radiation R1 and other parts in the resist film 5 with a second radiation R2 in a batch, and a step S50 as development of removing a part of the resist film 5 by development to form a resist pattern 5A having a trench 5a in which the underlayer film 3 is exposed. The first radiation R1 is ionizing radiation or non-ionizing radiation, and the second radiation R2 is non-ionizing radiation. In a case where the first radiation R1 is non-ionizing radiation, the second radiation R2 is non-ionizing radiation having a wavelength longer than the wavelength of the first radiation. The first radiation R1 may be extreme ultraviolet rays, and the second radiation R2 may be ultraviolet rays having a wavelength of 100 nm or more. The extreme ultraviolet rays are radiation having a wavelength less than 100 nm and is abbreviated to EUV. The wavelength of EUV may be, for example, 13.5 nm. The step S30 as post-exposure baking may not be performed.

The resist film 5 contains a resist material. The photoresist composition used to form the resist film 5 contains a resist material and a solvent. The resist material can be, for example, a metal oxide photoresist material or a chemically amplified photoresist material.

The metal oxide photoresist material can contain, for example, an organic metal compound containing a metal oxide having a metal atom and an organic ligand bonded to the metal atom. The metal oxide photoresist material may not contain an acid generator. The metal oxide photoresist material may be nanoparticles (particles having a maximum idth less than 1 μm). The metal oxide may be a cage-shaped compound. The metal oxide photoresist material containing an organic metal compound is considered to form a crosslinked structure through reactions including dissociation of the organic ligand from the metal atom by the irradiation with the first radiation R1 and bonding of the metal atoms after the dissociation of the organic ligand via an oxygen atom or the like by a condensation reaction. The formed crosslinked structure is substantially insoluble in a development material or developer solution. Therefore, the metal oxide photoresist material can function as a negative resist material. In a case where the metal oxide photoresist material is nanoparticles, the plurality of nanoparticles is linked to each other and can form an aggregate (crosslinked structure) that is substantially insoluble in a development material or developer solution. The formation of the aggregate can be facilitated mainly by post-exposure baking (step S30). After the aggregate is formed by the post-exposure baking or the like, by the batch exposure (step S40) with the second radiation R2, the parts (unexposed parts) other than the part 5E irradiated with the first radiation R1 in the resist film 45 go through a change in solubility in a development material or developer solution. Presumably, this is because the irradiation with the second radiation R2 forms a metal hydroxide from the metal oxide and leads to an increase in hydrophilicity (polarity) of the resist film. Based on the change in solubility resulting from the increase in hydrophilicity of the resist film by the second radiation R2, dissolution contrast during resist development increases. The increase in contrast is considered to contribute to a reduction in roughness of a resist pattern to be formed. That is, the roughness of the resist pattern to be formed can be further reduced by the batch exposure with the second radiation R2, compared to a case where the resist film is not irradiated with the second radiation R2 and a case where the resist film is irradiated with the second radiation R2 before irradiated with the first radiation R1.

The pattern exposure (step S20) by the first radiation R1 (for example, an extreme ultraviolet rays) and, in some cases, the batch exposure (step S40) after sufficient formation of the aggregates of the metal oxide photoresist material by the post-exposure baking (step S30) make it possible to facilitate the dissociation of the organic ligand and the formation of the metal hydroxide while suppressing the formation of aggregates (crosslinked structures) in parts other than the part 5E irradiated with the first radiation R1. This can contribute to the improvement of development contrast. In a case where the resist film is irradiated with the second radiation R2 before the pattern exposure (step S20) by the first radiation R1, the formation of aggregates also proceeds in parts other than the part 5E irradiated with the first radiation R1, which is likely to lead to contrast reduction. The batch exposure (step S40) with the second radiation (for example, ultraviolet rays having a wavelength of 100 nm or more) can cause dissociation of organic ligands remaining in the aggregates in the part 5E irradiated with the first radiation R1. Because the dissociation of the organic ligands makes the resist film hydrophilic, the solubility in an organic solvent decreases. As a result, sensitivity can be further improved.

The metal oxide of the metal oxide photoresist material may contain, for example, at least one metal atom selected from the group consisting of Sn, Sb, In, Ti, Zr, Hf, V, Co, Mo, W, Al, Ga, Si, Ge, P, As, Y, La, Ce, and Lu. The organic ligand bonded to the metal atom of the metal oxide may be, for example, a branched or non-branched alkyl group that may have a substituent or a cycloalkyl group that may have a substituent. The alkyl group and the cycloalkyl group can be bonded to a metal atom at a primary, secondary, or tertiary carbon atom. The alkyl group and the cycloalkyl group may have 1 to 30 carbon atoms. Examples of the alkyl group as the organic ligand include a methyl group, an ethyl group, an n-propyl group, an isopropyl group, an n-butyl group, a sec-butyl group, a tert-butyl group, and an n-octyl group. Examples of the cycloalkyl group as the organic ligand include a cyclobutyl group, a cyclopropyl group, a cyclohexyl group, a 1-adamantyl group, and a 2-adamantyl group. Examples of substituents that the alkyl group and the cycloalkyl group can have include a cyano group, an alkylthio group, a carbonyl group, an alkyloxy group, an alkylcarbonyl group, an alkylcarbonyloyl group, and a halogeno group. The nanoparticles containing cage-shaped tin oxide and an organic ligand can be, for example, a compound represented by Formula: [(SnR)₁₂O₁₄(OH)₆]OH)₂ (R represents an organic ligand).

The chemically amplified photoresist material forming the resist film 5 can contain a polymer component that becomes soluble or insoluble in a development material or a developer solution by the action of an acid and an acid generator that generates an acid by the first radiation R1. The chemically amplified photoresist material contains, as one or more components selected from the polymer component, the acid generator, and a component different from the polymer component and the acid generator, a sensitizer precursor component that enhances the absorption of the second radiation R2 into the resist material by exposure to the first radiation R1. In the part 5E of the resist film 5 irradiated with the first radiation R1, by the action of the acid generated from the acid generator, the solubility of the polymer component changes, and a component absorbing the second radiation R2 is generated from the sensitizer precursor component. Due to the generation of the component absorbing the second radiation R2, the part 5E irradiated with the first radiation R1 can selectively absorb the second radiation R2. It is considered that as a result, the acid generator in the part 5E irradiated with the first radiation R1 will go through decomposition or the like by the second radiation R2, and the solubility of the resist in the exposed part will thus increase and lead to an increase in development contrast, which may reduce the roughness of the resist pattern.

The polymer component or the acid generator contained in the chemically amplified photoresist material or either or both of the polymer component and the acid generator may be a compound that functions as the sensitizer precursor component. In a case where the chemically amplified photoresist material contains quenchers that are compounds neutralizing the acid generated from the acid generator, some or all of the quenchers may be a compound that functions as the sensitizer precursor component. The chemically amplified photoresist material may contain a compound different from the polymer component, the acid generator, and the quenchers, as a sensitizer precursor component. The sensitizer precursor component may be a component that enhances the absorption of the second radiation R2 into the resist film 5 by absorbing the first radiation R1.

The sensitizer precursor component can be, for example, a precursor compound that generates a sensitizer having a carbonyl group or a polymer component, an acid generator, or a quencher that includes a partial structure derived from the precursor compound. Examples of the precursor compound include an acetal compound, a ketal compound, a thioacetal compound, an alcohol compound, a thiol compound, and an orthoester compound. A compound (for example, a ketone compound) generated from these precursor compounds by the action of an acid generally absorbs the second radiation to enhance the absorption of the second radiation into the resist film.

The acetal compound, the ketal compound, and the thioacetal compound that can be used as the precursor compound may be, for example, a compound represented by the following Formula (1), and the compound is converted into a ketone compound represented by Formula (1A) by the action of an acid.

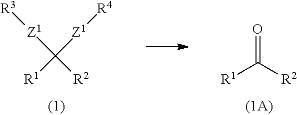

In Formulas (1) and (1A), Z¹ represents an oxygen atom or a sulfur atom, R¹ represents an aryl group that may have a substituent (for example, a phenyl group, a naphthyl group, or an anthracenyl group) or a conjugated diene group that may have a substituent, R² represents a hydrogen atom, a halogen atom, an aryl group that may have a substituent (for example, a phenyl group, a naphthyl group, or an anthracenyl group), a conjugated diene group that may have a substituent, a hydrocarbon group (for example, an alkyl group) having 1 to 30 or 1 to 5 carbon atoms that may have a substituent, an alkanoyl group having an alkyl group having 1 to 12 carbon atoms that may have a substituent, an amino group, or an aminocarbonyl group, and R³ and R⁴ each independently represent a hydrocarbon group (for example, an alkyl group) having 1 to 30 or 1 to 5 carbon atoms that may have a substituent. R¹ and R² may be bonded to each other directly or through a divalent group to form a cyclic structure, and R³ and R⁴ may be bonded to each other directly or through a divalent group to form a cyclic structure.

Examples of the divalent group configuring a cyclic structure formed by R¹ to R⁴ include —CH₂—, —O—, —S—, —SO₂—, —SO₂NH—, —C(═)O)—, —C(═O)O—, —NHCO—, —NHC(═)NH—, —CHR^{A}, —CR^{A} ₂—, —NH—, and —NR^{A}—. R^{A} represents a phenyl group, a phenoxy group, a halogen atom, a hydrocarbon group (for example, an alkyl group) having 1 to 30 or 1 to 5 carbon atoms, an alkoxy group having 1 to 5 carbon atoms, a hydroxyl group, a phenoxy group substituted with an alkyl group having 1 to 5 carbon atoms, or a phenyl group substituted with a hydrocarbon group (for example, an alkyl group) having 1 to 30 carbon atoms, an alkoxy group having 1 to 5 carbon atoms, or a hydroxyl group.

Examples of the substituent that the aryl group and the non-conjugated diene group as R¹ or R² can have include a hydrocarbon group having 1 to 30 or 1 to 5 carbon atoms (for example, an alkyl group), a hydroxyalkoxy group having 1 to 5 carbon atoms, a hydroxyalkyl group having 1 to 5 carbon atoms, an alkoxy group having 1 to 5 carbon atoms that may have a substituent, an amino group, an aminocarbonyl group, and a hydroxyl group. Examples of the substituent that the hydrocarbon group, the alkanoyl group, and the alkoxy group as R¹ to R⁴ can have include an alkoxy group having 1 to 5 carbon atoms, an alkoxycarbonyl group having an alkyl group with 1 to 5 carbon atoms, a cycloalkoxycarbonyl group having a cycloalkyl group with 5 to 30 carbon atoms, a furyl group, a phenoxy group, a naphthoxy group, an anthracenoxy group, an amino group, an aminocarbonyl group, and a hydroxyl group.

The acetal compound in which R³ and R⁴ are alkyl groups directly bonded to each other is represented, for example, by the following formulas. In these formulas, substituents such as an alkyl group having 1 to 5 carbon atoms, a cycloalkyl group having 3 to 30 carbon atoms, an alkoxy group having 1 to 5 carbon atoms, alkoxycarbonyl group having an alkyl group with 1 to 5 carbon atoms, a cycloalkoxycarbonyl group having a cycloalkyl group with 5 to 30 carbon atoms, a furyl group, a phenoxy group, a naphthoxy group, an anthracenoxy group, an amino group, an aminocarbonyl group, and a hydroxyl group may be bonded to the carbon atoms configuring the cyclic structure.

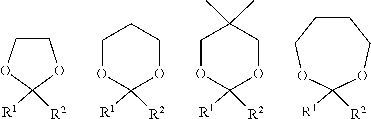

The alcohol compound and the thiol compound that can be used as the precursor compound may be, for example, a compound represented by the following Formula (2), and this compound is converted into a ketone compound represented by Formula (2A) by the action of an acid.

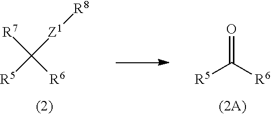

In Formulas (2) and (2A), Z¹ represents an oxygen atom or a sulfur atom, R⁵ represents an aryl group that may have a substituent (for example, a phenyl group, a naphthyl group, or an anthracenyl group) or a conjugated diene group that may have a substituent, R⁶ represents an aryl group that may have a substituent (for example, a phenyl group, a naphthyl group, or an anthracenyl group), a conjugated diene group that may have a substituent, a hydrocarbon group (for example, an alkyl group) having 1 to 30 or 1 to 5 carbon atoms that may have a substituent, an alkanoyl group having an alkyl group with 1 to 12 carbon atoms that may have a substituent, an amino group, or an aminocarbonyl group, R⁷ represents a hydrogen atom or a halogen atom, and R⁸ represents a hydrogen atom. R⁵ and R⁶ may be bonded to each other directly or through a divalent group to form a cyclic structure. The aryl group and the non-conjugated diene group as Ror R⁶ may have the same substituents as the substituents that the aryl group and the conjugated diene group as R¹ or R² can have. The divalent groups configuring the cyclic structure formed by R⁵ and R⁶ can be the same groups as the divalent groups configuring the cyclic structure formed by R¹ to R⁴.

The orthoester compound that can be used as the precursor compound may be, for example, a compound represented by Formula (3) or (4), and each of these compounds is converted into an ester compound represented by Formula (3A) or a carboxylic acid compound represented by Formula (4A) by the action of an acid.

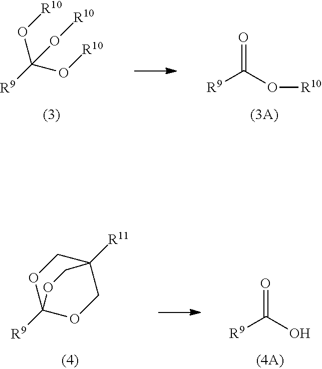

In Formulas (3) and (4), R⁹ represents an aryl group that may have a substituent (for example, a phenyl group, a naphthyl group, or an anthracenyl group), R¹⁰ represents a hydrocarbon group having 1 to 30 carbon atoms that may have a substituent (for example, an alkyl group), and a plurality of R¹⁰s in the same molecule may be the same as or different from each other. Examples of the substituent that the aryl group as R⁹ can have include an alkyl group having 1 to 30 or 1 to 5 carbon atoms, an aryloxy group, an arylalkyl group having an alkyl group having 1 to 5 carbon atoms, an arylalkyloxy group having an alkyl group having 1 to 5 carbon atoms, a hydroxyalkoxy group having 1 to 5 carbon atoms, a hydroxyalkyl group having 1 to 5 carbon atoms, an alkoxy group having 1 to 5 carbon atoms, an amino group, an aminocarbonyl group, and a hydroxyl group. The aryl group as R⁹ may include two or more aromatic rings bonded to each other directly or through a divalent group at two or more sites. R¹¹ in Formula (4) represents a hydrogen atom, a hydrocarbon group (for example, an alkyl group) having 1 to 30 or 1 to 5 carbon atoms that may have a substituent, an aryl group that may have a substituent (for example, a phenyl group, a naphthyl group, or an anthracenyl group), an alkoxy group having 1 to 5 carbon atoms that may have a substituent, or an aryloxy group (for example, a phenoxy group, a naphthoxy group, or an anthracenoxy group) that may have a substituent. Examples of the substituent that the hydrocarbon group, the aryl group, the alkoxy group, and the aryloxy group as R¹¹ can have include an alkoxy group having 1 to 5 carbon atoms, an alkoxycarbonyl group having an alkyl group with 1 to 5 carbon atoms, a cycloalkoxycarbonyl group having a cycloalkyl group with 5 to 30 carbon atoms, a furyl group, a phenoxy group, a naphthoxy group, an anthracenoxy group, an amino group, an aminocarbonyl group, and a hydroxyl group.

More specific examples of the ketal compound that can be used

as the precursor compound include compounds represented by the following Formula (11) or (12).

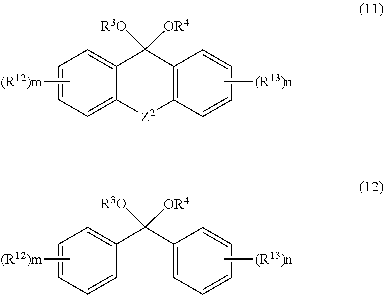

In Formulas (11) and (12), R³ and R⁴ have the same definition as R³ and R⁴ in Formula (1), R¹² and R¹³ each independently represent a hydrocarbon group (for example, an alkyl group) having 1 to 30 or 1 to 5 carbon atoms, a hydroxyalkoxy group having 1 to 5 carbon atoms, a hydroxyalkyl group having 1 to 5 carbon atoms, an alkoxy group having 1 to 5 carbon atoms that may have a substituent, an amino group, an aminocarbonyl group, or a hydroxyl group, and two R¹²s or R¹³s may be bonded to each other directly or through a divalent group to form a cyclic structure. in and n each independently represent an integer of 0 to 4, and a plurality of R¹²s in the same molecule may be the same as or different from each other. In Formula (11), Z² represents a divalent group selected from —O—, —S—, and —NR^{A}—. R^{A} is the same group as R^{A} described above. Examples of the substituent that the alkoxy group as R¹² or R¹³ can have include an alkyl group having 1 to 5 carbon atoms.

R¹² and R¹³ may be a hydroxyalkoxy group having 1 to 5 carbon atoms, and two R¹²s or two R¹³s may be bonded to each other to form a group represented by the following formula.

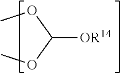

R¹⁴ represents an alkyl group having 1 to 5 carbon atoms. In this case, examples of the acetal compound are represented by the following Formula (11a) or (11b). In Formula (11a), R¹⁵ and R¹⁶ represent an alkyl group having 1 to 5 carbon atoms or a hydroxyalkyl group having 1 to 5 carbon atoms.

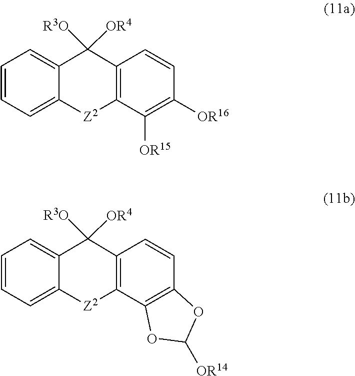

The polymer component can be selected from general polymers configuring a chemically amplified photoresist material. For example, the polymer component may be a polymer containing a monomer unit having a group that generates a polar group by the action of an acid. The monomer unit having a group that forms a polar group by the action of an acid is represented, for example, by the following Formula (21) or (22). The polymer component that functions as the sensitizer precursor component may be a polymer further containing a monomer unit having a partial structure derived from the aforementioned precursor compound.

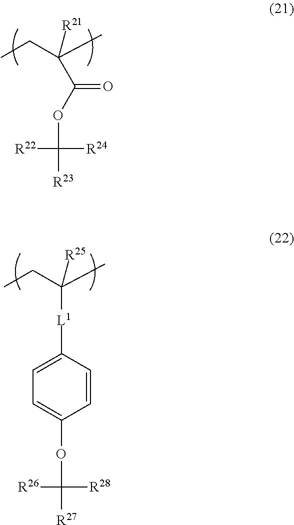

In Formula (21), R²¹ represents a hydrogen atom, a fluorine atom, a methyl group, or a trifluoromethyl group, R²² represents a monovalent hydrocarbon group having 1 to 20 carbon atoms, and R²³ and R²⁴ each independently represent a linear or branched hydrocarbon group having 1 to 20 carbon atoms or groups that are bonded to each other to form a 3- or 20-membered cyclic hydrocarbon group.

In Formula (22), R²³ represents a hydrogen atom, a fluorine atom, a methyl group, or a trifluoromethyl group, R²⁶ represents a hydrogen atom, a monovalent hydrocarbon group having 1 to 20 carbon atoms, or a monovalent oxyhydrocarbon group having 1 to 20 carbon atoms, R²⁷ and R²⁸ each independently represent a monovalent hydrocarbon group having 1 to 20 carbon atoms or a monovalent oxyhydrocarbon group having 1 to 20 carbon atoms, and L¹ represents a single bond, 'O—, —COO—, or —CONH—. The oxyhydrocarbon group is a group having two or more hydrocarbon groups and an oxy group interposed therebetween.

The acid generator may include a sulfonium salt, an iodonium salt, or a combination of these. The acid generator that functions as a sensitizer precursor component may be a sulfonium salt or an iodonium salt having a partial structure derived from the aforementioned precursor compound. Examples of the acid generator that functions as a sensitizer precursor component include compounds represented by the following Formula (31), (32), (33), or (34).

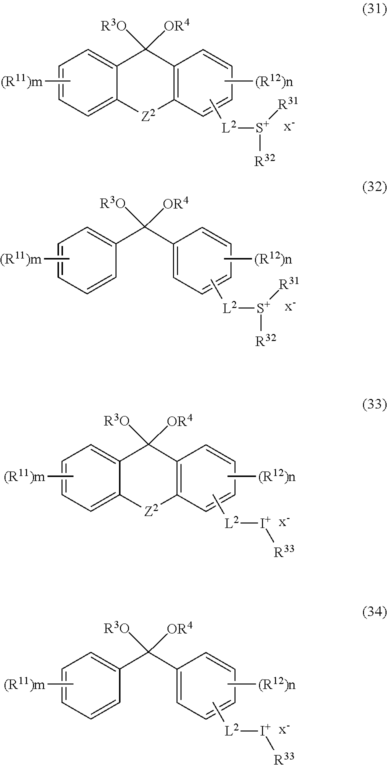

R³, R⁴, R¹¹, R¹², and Z² in Formulas (31) to (34) have the same definition as R³, R⁴, R¹¹, R¹², and Z² in Formula (11) or (12).

R³¹ and R³² in Formulas (31) and (32) each independently

represent any one selected from the group consisting of a linear, branched, or cyclic alkyl group having 1 to 12 carbon atoms that may have a substituent, a linear, branched, or cyclic alkenyl group having 1 to 12 carbon atoms that may have a substituent, an aryl group having 6 to 14 carbon atoms that may have a substituent, a heteroaryl group having 4 to 12 carbon atoms that may have a substituent. Any two or more among R³¹, R³², and a sulfonium group-bonded aryl group may be connected directly by a single bond or connected through any one selected from the group consisting of an oxygen atom, a sulfur atom, a nitrogen atom-containing group, and a methylene group to form a ring structure together with sulfur atoms to which these groups are bonded. At least one methylene group configuring R³¹ or R³² may be substituted with a divalent heteroatom-containing group.

R³³ in Formulas (33) and (34) represents an aryl group that may

have a substituent or a heteroaryl group that may have a substituent. R³³ and an iodonium group-bonded aryl group may be bonded to each other to form a ring structure together with iodine atoms to which these groups are bonded.

In Formulas (31) to (34), L² represents any one selected from the group consisting of a direct bond, a linear, branched, or cyclic alkylene group having 1 to 12 carbon atoms, an alkenylene group having 1 to 12 carbon atoms, an arylene group having 6 to 14 carbon atoms, a heteroarylene group having 4 to 12 carbon atoms, and a group configured with these groups bonded through an oxygen atom, a sulfur atom, or a nitrogen atom-containing group.

In Formulas (31) to (34), X⁻ represents a monovalent counter anion. Examples of X⁻ include a sulfonate anion, a carboxylate anion, an imide anion, a methide anions, a carbanion, a borate anion, a halogen anion, a phosphate anion, an antimonate anion, and an arsenate anion.

The quencher may contain a sulfonium salt, an iodonium salt, or a combination of these. The acid generator that functions as a sensitizer precursor component may be a sulfonium salt or an iodonium salt having a partial structure derived from the aforementioned precursor compound.

In the photoresist composition or the resist film 5 formed of the photoresist composition and not yet being exposed, the amount of the sensitizer precursor component (the amount of the precursor compound or the amount of the partial structure derived from the precursor compound) may be 0.1 to 40 parts by mass or 1 to 20 parts by mass with respect to 100 parts by mass of the chemically amplified resist material (or the resist film 5).

The solvent configuring the photoresist composition used to form the resist film 5 is selected from solvents capable of dispersing or dissolving the resist material. Examples of the solvent include ketones such as cyclohexanone and methyl-2-amylketone; alcohols such as 3-methoxybutanol, 3 -methyl-3 -methoxybutanol, 1-methoxy-2-propanol, and 1-ethoxy-2-propanol; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; and esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, propylene glycol monomethyl ether acetate, and propylene glycol monotert-butyl ether acetate.

The amount of the solvent in the photoresist composition is

adjusted within a range in which the resist film 5 can be appropriately formed by a method such as spin coating. For example, the amount of the solvent may be 500 to 100,000 parts by mass with respect to 100 parts by mass of the resist material (for example, the metal oxide photoresist material or the chemically amplified resist material).

The underlayer film 3 is coated with the photoresist composition by, for example, spin coating (step S10). The photoresist composition with which the underlayer film 3 is coated is baked such that the solvent in the photoresist composition is removed (step S11). The resist film 5 formed in advance may be laminated on the underlayer film 3. The thickness of the resist film 5 may be, for example, 1 to 5,000 nm, 10 to 1,000 nm, or 30 to 200 nm.

Instead of the method of coating and baking of the photoresist composition, a vapor deposition method may be used to form the resist film 5. Examples of the applicable vapor deposition method include physical vapor deposition (PVD), chemical vapor deposition (CVD), and atomic layer deposition (ALD). The resist film 5 containing a metal oxide photoresist material may be formed by a vapor deposition method including supplying a reaction gas to a vapor phase to which the underlayer film 3 is to be exposed, the reaction gas containing a precursor of an organic metal compound configuring the metal oxide photoresist material and a co-precursor (for example, water) reacting with the precursor to produce an organic metal compound. The organic metal compound generated by the reaction between the precursor and the co-precursor in the vapor phase may be deposited on the underlayer film 3. Alternatively, the organic metal compound may be generated by the reaction between the precursor deposited on the underlayer film 3 and the co-precursor.

The underlayer film 3 may be a film containing a silicon-containing material that contains a silicon atom and a carbon atom bonded to the silicon atom. The underlayer film 3 containing the silicon-containing material can be, for example, a film formed by heating a film of a composition containing polycarbosilane having an organic group bonded to a silicon atom or polysiloxane having an organic group bonded to a silicon atom. The underlayer film 3 containing the silicon-containing material readily absorbs the second radiation R2 (for example, ultraviolet rays having a wavelength of 100 nm or more). Therefore, the irradiation with the second radiation R2 particularly facilitates the dissociation of the organic ligand in the region (lower region) near the underlayer film 3 in the resist film 5, and such a region can become hydrophilic. In a case where the region near the underlayer film 3 of the resist film 5 becomes hydrophilic, the solubility of the part 5E irradiated with the first radiation R1 (for example, an extreme ultraviolet rays) in a development material is reduced particularly when the development material is an organic material. Therefore, the wall surface of the resist pattern does not significantly tilt relative to the underlayer film 3, and it is easy to form a resist pattern having a wall surface that is perpendicular to the thickness direction of the underlayer film 3 or extends in a direction nearly perpendicular to the thickness direction of the underlayer film 3. Note that, presumably, compared to the irradiation with the second radiation R2 before the formation of the resist film 5, the irradiation with the second radiation R2 after the formation of the resist film 5 may further facilitate the dissociation of the organic ligand in the lower region of the resist film 5, that is, further facilitate the hydrophilic modification. As the reason, it is considered that in a case where the irradiation with the second radiation R2 is carried out before the formation of the resist film 5, due to the lapse of time until the formation of the resist film 5, the effect of facilitating the dissociation of the organic ligand in the lower region of the resist film 5 by the underlayer film may relatively weaken. Even though the irradiation with the second radiation R2 is carried out after the formation of the resist film 5, because the wavelength of the second radiation R2 is sufficiently longer than the wavelength of EUV, the second radiation R2 reaches the underlayer film 3.

The formed resist film 5 is irradiated with the first radiation R1 through a mask 7 with openings placed on the resist film 5 (step S20). As a result, in the resist film 5, the part (5E) exposed in the openings of the mask 7 is irradiated with the first radiation R1 having a pattern corresponding to the openings.

The first radiation R1 may be ionizing radiation or non-ionizing radiation having a wavelength of 300 nm or less. The light source of the first radiation R1 may be, for example, an electron beam of 1 kev to 200 kev, extreme ultraviolet rays (EUV) having a wavelength of about 13.5 nm, a 193 nm excimer laser (ArF excimer laser), or a 248 nm excimer laser (KrF excimer laser). The dose of the first radiation R1 may be, for example, 5 to 300 mJ/cm². The exposure with the first radiation R1 can be performed by immersion lithography or dry lithography. The first radiation R1 may be radiated along a predetermined pattern instead of using a mask.

After the irradiation with the first radiation R1, the mask 7 is removed, and then the resist film 5 is baked (step S30). The heating for baking after pattern exposure by the first radiation R1 can be performed in the atmosphere, in an inert gas atmosphere such as nitrogen or argon, or in a humid environment. The pressure in the atmosphere of the post-exposure baking may be atmospheric pressure or may be lower than atmospheric pressure. The heating temperature may be 50° C. to 250° C. or 170 to 250° C., and the heating time may be 10 to 300 seconds or 50 to 300 seconds. In a case where the heating temperature for the post-exposure baking is high, development contrast can be further improved when the development material is an alkaline aqueous solution or water. The post-exposure baking may be one-step heating at a constant temperature or may include two or more heating steps at different temperatures. For example, the post-exposure baking may include a first step of heating at a temperature of 80° C. to 170° C. and a second step of heating at a temperature of 180° C. to 250° C. The first step may be performed in the atmosphere or in a humid environment such that the formation of a metal hydroxide is facilitated by a hydrolysis reaction. The second step may be performed under atmospheric pressure, in an atmosphere under reduced pressure, or in an inert gas environment.

Next, in the resist film 5, the entire region including the part 5E irradiated with the first radiation R1 and other parts is irradiated with the second radiation R2 in a batch (step S40, batch exposure). When the resist film is irradiated with the second radiation R2, the solubility of the part 5E irradiated with the first radiation R1 in a development material or a developer solution selectively changes. In the present specification, the batch exposure includes not only a case where the entire region including the part 5E irradiated with the first radiation R1 and other parts in the resist film 5 is simultaneously exposed to ultraviolet rays, but also a case where the exposed region is moved while a part of the region is being exposed such that the entire region is exposed.

In a case where the second radiation R2 is non-ionizing radiation and the first radiation R1 is ionizing radiation, the wavelength of the second radiation R2 may be longer than the wavelength of the first radiation R1. For example, the second radiation R2 may be ultraviolet rays having a wavelength of 100 nm or more and 450 nm or less or 100 nm or more and 300 nm or less. The second radiation R2 may be ultraviolet rays having a wavelength of 254 nm, 279 nm, 280 nm, 365 nm, 385 nm, or 395 nm, or may be ultraviolet rays having a wavelength of 254 nm, 270 nm, or 280 nm. The second radiation R2 may be ultraviolet rays having a wavelength of 170 nm or more, 200 nm or more, or 250 nm or more. The ultraviolet rays having a wavelength of 170 nm or more are suitable, for example, for batch exposure in the atmosphere. The ultraviolet rays having a wavelength of 200 nm or more can suppress a side reaction such as an oxidation reaction. The light source of the second radiation R2 may be, for example, a mercury lamp, a xenon lamp, LED, or a laser light source. These can be easily mounted on an exposure unit that will be described later. LED is particularly excellent in terms of high-precision control of exposure amount and long-term stability of exposure amount. Therefore, LED can be used to control the size of the resist pattern with high accuracy. The dose of the second radiation (for example, the ultraviolet rays from LED) is, for example, 0.005 to 100 cm², 0.005 to 90 J/cm², 0.005 to 80 J/km², 0.005 to 70 J/cm², 0.005 to 60 J/cm², 0.005 to 50 J/cm², 0.005 to 40 J/cm², 0.005 to 30 J/cm², or 0.005 to 20 J/cm². The dose of the second radiation R2 may be 1 J/cm² or more, 2 J/cm² or more, 3 J/cm² or more, 4 J/cm² or more, or 5 J/cm² or more. The exposure by the second radiation R2 can be performed by immersion lithography or dry lithography.

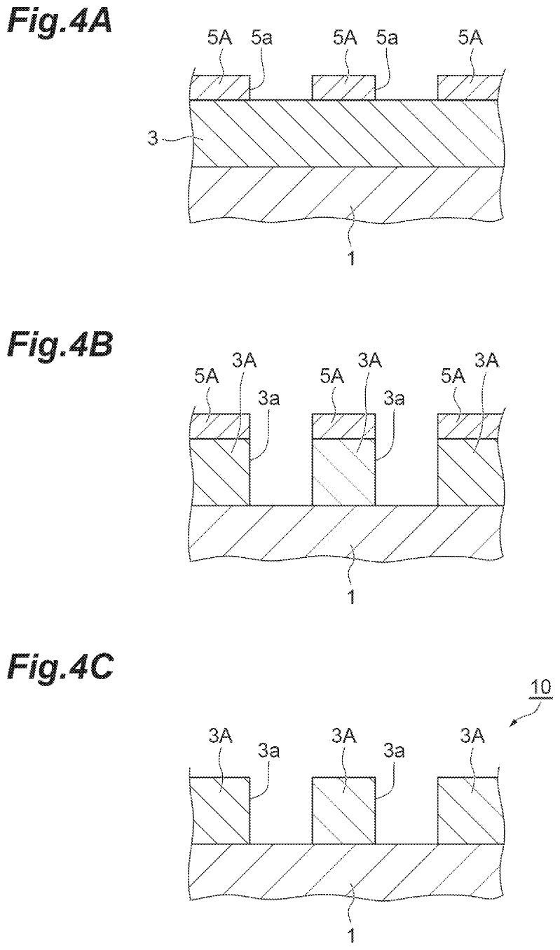

Subsequently, a part of the resist film 5 is removed by development such that the resist pattern 5A having the trench 5a in which the underlayer film 3 is exposed is formed (step S50, FIG. 4A). In a case where the resist film 5 is a negative resist, the part 5E irradiated with the first radiation R1 substantially does not dissolve in a development material or a developer solution, and remains as the resist pattern 5A. In a case where the resist film 5 is a positive resist, contrary to the embodiment illustrated in the drawing, the part 5E irradiated with the first radiation R1 is removed, and other parts remain as the resist pattern 5A. The development can be wet development including bringing

the resist film 5 into contact with a developer solution, or dry development including exposing the resist film 5 to a developer gas.

The developer solution for wet development is selected from substances that efficiently dissolve the part 5E irradiated with the first radiation R1 or other parts. The developer solution can be, for example, an organic developer solution, an alkaline developer solution (an alkaline aqueous solution), or water.

In a case where the resist material is a negative resist material (for example, a metal oxide photoresist material or a chemically amplified photoresist material), the developer solution may be an organic developer solution. Examples of the organic developer solution include methyl acetate, butyl acetate, ethyl acetate, isopropyl acetate, amyl acetate, isoamyl acetate, ethyl methoxyacetate, ethyl ethoxyacetate, 2-heptanone, propylene glycol monomethyl ether acetate, isopropyl alcohol, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate (PGMEA), propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentylacetate, 3-methyl-3-methoxypentylacetate, 3-methyl-4-methoxypentylacetate, 4-methyl-4-methoxypentylacetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetate, ethyl acetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. The organic developer solution may be a mixture of these and an organic acid (such as acetic acid or citric acid). The organic developer solution may be butyl acetate, 2-heptanone, propylene glycol monomethyl ether acetate, or a mixture of these and an organic acid (such as acetic acid or citric acid). After the development with an organic developer solution, the resist pattern may be rinsed with an alkaline aqueous solution (for example, an aqueous tetramethylammonium hydroxide solution) or water to remove the hydrophilic part of the unexposed part.

The developer solution may be an alkaline aqueous solution. The alkaline aqueous solution used as the developer solution may contain, for example, alkaline components including inorganic alkalis such as sodium hydroxide, potassium hydroxide, sodium carbonate, sodium silicate, sodium metasilicate, and aqueous ammonia, primary amines such as ethylamine and n-propylamine, secondary amines such as diethylamine and di-n-butylamine, tertiary amines such as triethylamine and methyldiethylamine, alcohol amines such as dimethylethanolamine and triethanolamine, quaternary ammonium salts such as tetramethylammonium hydroxide, tetraethylammonium hydroxide, and choline, and cyclic amines such as pyrrol and piperidine. The alkaline aqueous solution may contain alcohols such as isopropyl alcohol and surfactants such as a nonionic surfactant. The developer solution may be an alkaline aqueous solution containing a quaternary ammonium salt, tetramethylammonium hydroxide, or tetrabutylammonium hydroxide. The rinsing after development with an alkaline aqueous solution can be performed using water or an organic solvent.

The developer gas for dry development may be an acidic gas. The acidic gas can be, for example, a gas containing one or more acid components selected from HBr, acetic acid, and BCl₃. The developer gas may include a gas formed by vaporization of the aforementioned developer solution. The dry development may be performed under atmospheric pressure or may be performed in an environment under pressure lower than atmospheric pressure.

After the development process, the end face and back surface of the semiconductor wafer 1 may be cleaned with a cleaning liquid. The cleaning liquid may be water, an alkaline aqueous solution, or an organic solvent. The organic solvent may contain an acid component or an alkaline component.

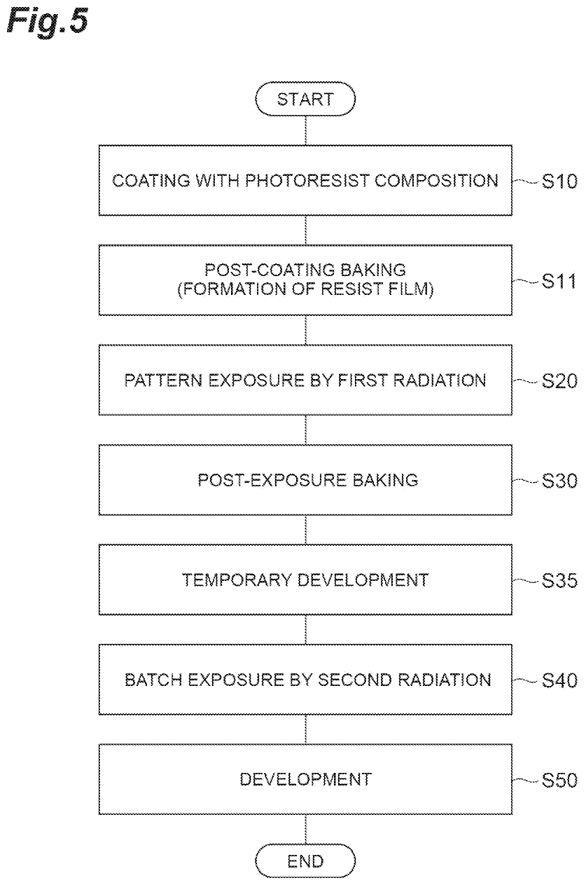

FIG. 5 is a flowchart illustrating another example of a method for forming a resist pattern. The method illustrated in FIG. 5 includes a temporary development step (step S35) of preliminarily developing the resist film after the post-exposure baking (step S30), prior to the batch exposure (step S40) by the second radiation. The temporary development can be wet development by contact with a developer solution or dry development. The temporary development can further improve sensitivity. The temporary development can be effective particularly, for example, for a metal oxide photoresist material used as a resist material. The temporary development may be wet development by a developer solution, and the development after the batch exposure may be wet development by a developer solution or dry development. After the temporary development, the critical dimension (CD) of the resist pattern may be measured, and the dose for the batch exposure may be adjusted based on the measured critical dimension.

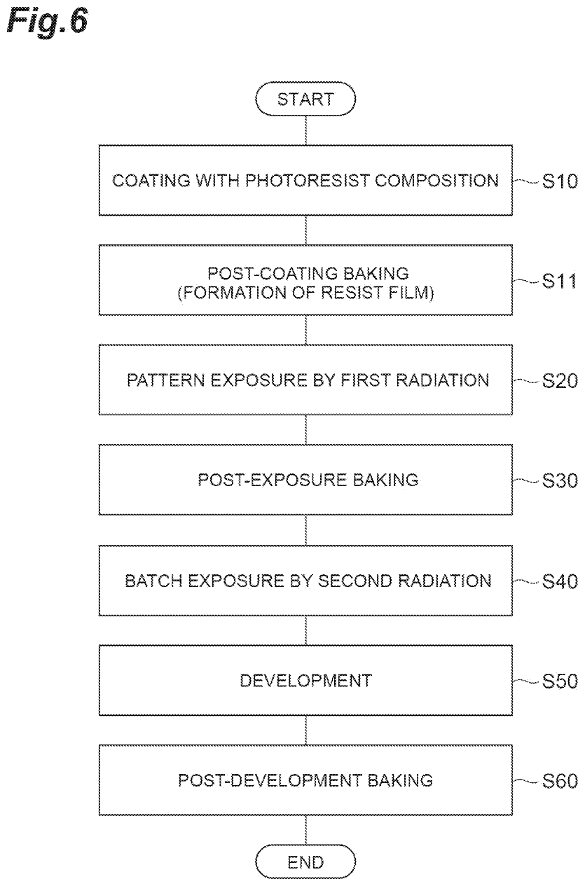

FIG. 6 is a flowchart illustrating still another example of a method for forming a resist pattern. The method illustrated in FIG. 6 differs from the method illustrated in FIG. 1 in that this method includes a post-development baking step S60 of baking the formed resist pattern after the development step S50. The temperature for the post-development baking may be higher than the temperature in the post-exposure baking step S30, and may be, for example, 230 to 300° C. The heating time for the post-exposure baking may be 30 to 300 seconds. The post-development baking makes it possible to efficiently remove the residues in the region other than the part 5E irradiated with the first radiation R1 (for example, an extreme ultraviolet rays). In the region (unexposed part) other than the part 5E irradiated with the first radiation R1, the dissociation of the organic ligand is facilitated by the irradiation with the second radiation R2 (for example, ultraviolet rays having a wavelength of 100 nm or more), which causes the resist material to be depolymerized and in a state of being readily vaporized by heat. Therefore, the combination of the irradiation with the second radiation R2 and the post-exposure baking makes it possible to efficiently remove the residues of the resist material. Presumably, in a case where the temperature of the post-development baking is higher than the temperature of the post-exposure baking, the residues may be readily decomposed, and the removal efficiency may be further improved.

The condition of the development step S50 may be the condition where the resist film is preliminarily developed, and the development may be completed by the post-development baking step S60. In this case, because the resist pattern is not completely resolved in the development step S50, it is particularly unlikely that the pattern will be distorted or collapse. Furthermore, since no liquid is used in the post-development baking step S60, it is possible to adjust the pattern shape while avoiding the distortion and collapse of the pattern resulting from the surface tension of a liquid. The pattern shape adjustment includes, for example, forming a resist pattern having a size larger than a target size and/or a surface rougher than a target roughness in the development step S50 and reducing the size and/or surface roughness of the resist pattern in the post-development baking step S60 to form a resist pattern having size and roughness closer to the target size and roughness.

The method for forming a resist pattern may include further exposing the resist pattern formed by development to ultraviolet rays. In this way, the durability of the resist pattern can be further improved. The light source of the ultraviolet rays for the post-development exposure may be LED or a UV lamp that emits light having a peak between 160 nm and 420 nm.

As illustrated in FIGS. 4B and 4C, the method for producing a semiconductor device further includes etching the underlayer film 3 which is an etching target film exposed in the trench 5a of the resist pattern 5A such that an underlayer film 3A patterned to form a trench 3a is formed. The method of etching the underlayer film 3 can be selected in consideration of the type of material configuring the underlayer film 3 and the like. For example, dry etching or wet etching may be used. After the etching, the resist pattern 5A may be removed. By the method illustrated in FIGS. 4B and 4C, a processed substrate 10 having the semiconductor wafer 1 and the patterned underlayer film 3A is obtained.

The patterned underlayer film 3A may be, for example, a film that includes an active layer, a lower layer insulating film, a gate electrode film, or an upper layer insulating film. Wiring may be embedded in the trench 3a of the underlayer film 3A. By the method according to the present disclosure, for example, it is possible to manufacture a semiconductor device including a semiconductor substrate and an integrated circuit including a patterned underlayer film formed on the semiconductor substrate.

By the etching using the resist pattern formed by the method according to the present disclosure as a mask, it is also possible to manufacture a mask for lithography or template for nanoimprinting. The mask for lithography may be a transmissive mask or a reflective mask.

For the method exemplified above, for example, it is possible to use a substrate processing device mainly configured with a heat treatment unit (heater) that bakes a resist film formed on a workpiece having an underlayer film, an exposure unit (irradiator) that radiates a second radiation to the resist film having a part irradiated with a first radiation, a development unit (developer) that removes a part of the resist film by development to form a resist pattern, and a control unit (circuit) that controls the exposure unit such that the entire region including the part irradiated with the first radiation and other parts in the resist film is irradiated with the second radiation in a batch. The heat treatment unit has, for example, a hot plate. The development unit has, for example, a supply source (a storage container) of a development material (a developer solution or a developer gas), a member (for example, a nozzle or a shower head) that supplies a development material, and a supply pipe that connects the supply source and the member supplying the development material.

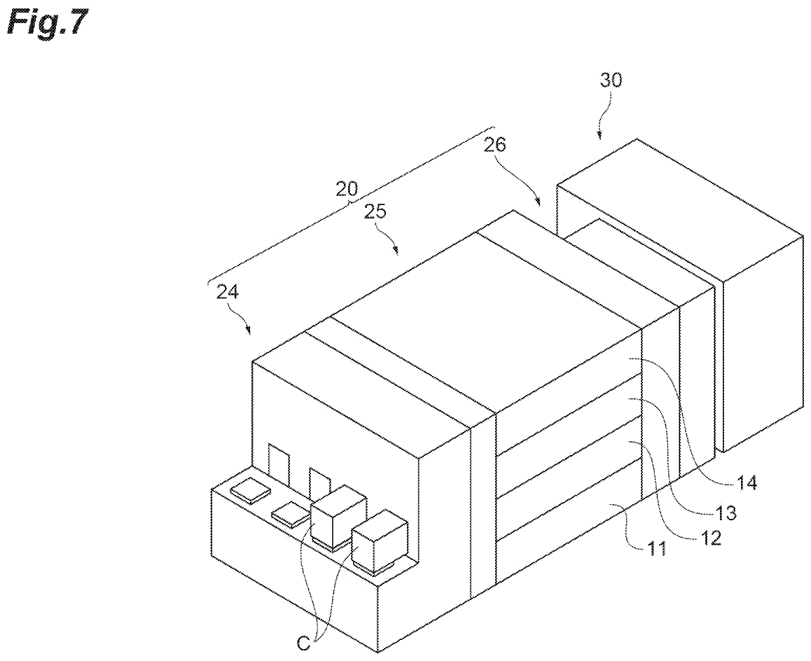

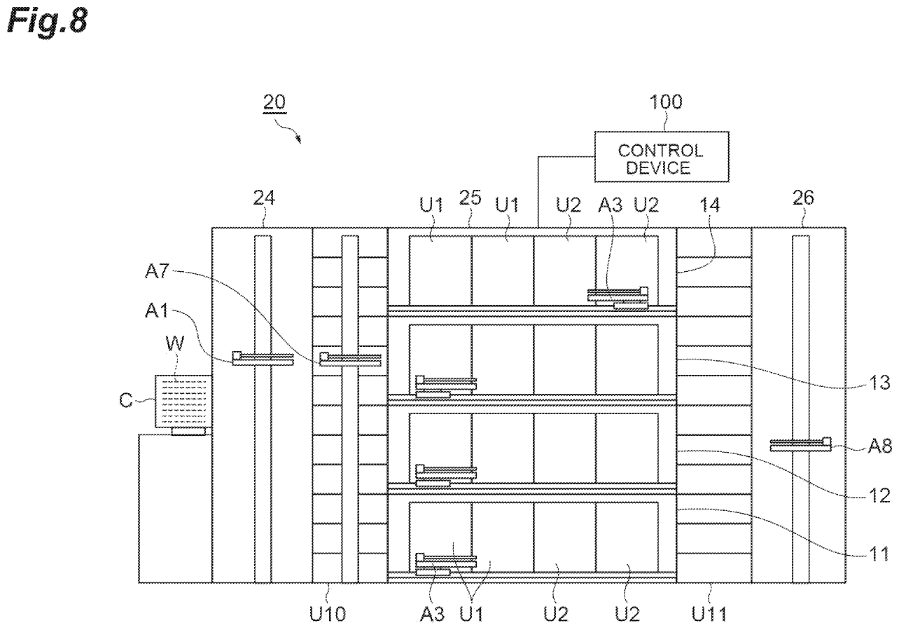

FIGS. 7 and 8 are schematic views illustrating an example of a substrate processing device. FIG. 7 also illustrates an example of an exposure device used in combination with the substrate processing device. FIG. 8 illustrates an example of an internal configuration of a substrate processing device 20 illustrated in FIG. 7. The substrate processing device 20 illustrated in FIGS. 7 and 8 includes a carrier block 24, a processing block 25, and an interface block 26. The workpiece W is processed with the substrate processing device 20 by the above method.

The carrier block 24 is a block configured to introduce the workpiece W into the substrate processing device 20 and to take the workpiece W out of the substrate processing device 20. The carrier block 24 has a transport device A1 including a delivery arm. The transport device A1 takes out the workpiece W stored in a carrier C, passes the workpiece W to the processing block 25, receives the workpiece W from the processing block 25, and returns the workpiece W back into the carrier C.

The processing block 25 has processing modules 11, 12, 13, and 14, which are laminated in this order. The processing modules 11, 12, 13, and 14 each have a plurality of built-in processing units U1 and U2, and a built-in transport device A3 that transports the workpiece W to these processing units.

The processing module 11 may be configured to form an underlayer film (etching target film) on the surface of a substrate (for example, a semiconductor wafer) as the workpiece W. In the processing module 11, for example, the processing unit U1 may be a liquid processing unit that coats the workpiece W with a coating liquid for forming an underlayer film, and the processing unit U2 may be a heat treatment unit that thermally treats the coating liquid with which the workpiece W is coated to form an underlayer film.

The processing module 12 may be configured to form a resist film on the underlayer film (etching target film) of the workpiece W. In the processing module 12, for example, the processing unit U1 may be a coating unit that coats the workpiece W with a photoresist composition, and the processing unit U2 may be a heat treatment unit that bakes the photoresist composition with which the workpiece W is coated to form a resist film. The workpiece W having the resist film may be transported to an exposure device 30 through the interface block 26, and a part of the resist film may be irradiated with the first radiation (for example, an extreme ultraviolet rays) in the exposure device 30.

The processing module 13 may be configured to bake the resist film having a part irradiated with the first radiation in the exposure device and then to irradiate the entire resist film with the second radiation (for example, ultraviolet rays having a wavelength of 100 nm or more). In the processing module 13, for example, the processing unit U1 may be a heat treatment unit for baking the resist film not yet being irradiated with the second radiation, and the processing unit U2 may be an exposure unit having a light source of the second radiation.

The exposure unit for irradiating the resist film with the second radiation can have a light source module of the second radiation immobilized inside the exposure unit. In this case, the workpiece W may pass through an exposure region exposed to the second radiation from the light source module such that the resist film is irradiated with the second radiation. The exposure unit may have a mechanism for rotating the workpiece W while the workpiece W is passing through the exposure region. Irradiating the workpiece W with the second radiation while rotating the workpiece W makes it possible to suppress the variation in the radiation dose.

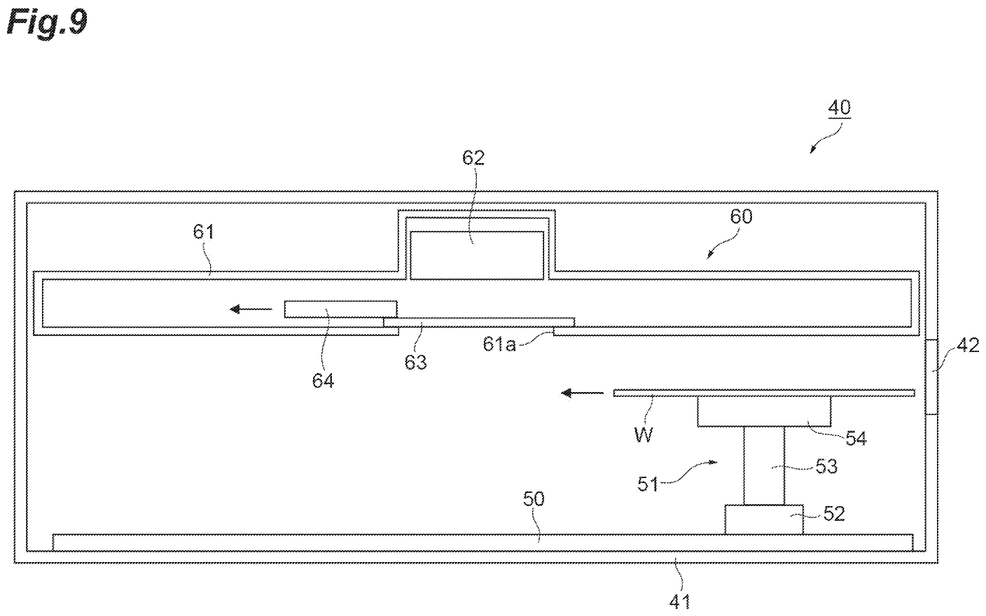

FIG. 9 is a schematic view illustrating an example of an exposure unit. An exposure unit 40 illustrated in FIG. 9 has a rectangular case 41, and a moving mechanism portion 50, a support 51, and a light source module 60 provided on the inside of the case 41. A transportation port as an opening for moving the workpiece W in and out is provided on the side wall of the case 41. The moving mechanism portion 50 is provided on the bottom internal surface of the case 41, and the support 51 is mounted on the moving mechanism portion 50. The support 51 has a support stand 52 fixed to the moving mechanism portion 50, a rotary portion 53 extending vertically upward from the support stand 52, and a disk-shaped mounting platform 54 attached to the upper end of the rotary portion 53. The workpiece W introduced from the transportation port 42 is mounted on the mounting platform 54. The mounting platform 54 adsorbs and holds the workpiece W. Usually, the case 41 is disposed such that the bottom surface thereof provided with the moving mechanism portion 50 becomes horizontal, and the workpiece W is held on the mounting platform 54 such that the main surface thereof becomes horizontal.

In the case 41, the light source module 60 is provided above the moving mechanism portion 50 and the support 51. The light source module 60 has a case 61 and a light source 62 provided on the inside of the case 61. The case 61 has an opening 61a formed immediately below the light source 62, and is also provided with a shutter 63 for opening and closing the opening 61a. By a shutter-moving mechanism portion 64 provided on the inside of the case 61, the shutter 63 moves between a closing position for closing the opening 61a and an opening position for opening the opening 61a.

In a state where the light source 62 is turned on and the shutter 63 has moved to the opening position to open the opening 61a, the support 51 is moved in the horizontal direction on the inside of the case 41 by the moving mechanism portion 50, resulting in the irradiation of the entire resist film of the workpiece W with the second radiation. In the meantime, the rotary portion 53 rotates, making the workpiece W rotate around the central axis thereof.

The processing module 14 may be configured to function as a development unit which removes a part of the resist film irradiated with the second radiation by contact with a development material or a developer solution such that a resist pattern is formed. In the processing module 14, for example, the processing unit U1 may be a liquid processing unit that supplies a development material or a developer solution and, as necessary, a rinsing liquid to the resist film, and the processing unit U2 may be a heat treatment unit for thermally treating the resist film before development. Sequentially performing the batch exposure with the second radiation by the exposure unit in line with the baking by the heat treatment unit and the development by the liquid processing unit is advantageous in terms of shortening the process time and suppressing the influence of the size variation of the resist film during the process.

The processing block 25 further has a shelf unit U10 provided on the carrier block 24 side. The shelf unit U10 is divided into a plurality of cells arranged in the vertical direction. A transport device A7 including a lifting arm is provided near the shelf unit U10. The transport device A7 moves the workpiece W up and down between cells of the shelf unit U10. The processing block 25 has a shelf unit U11 provided on the interface block 26 side. The shelf unit U11 is divided into a plurality of cells arranged in the vertical direction.

The interface block 26 is configured to deliver the workpiece W between the processing block 25 and the exposure device 30. The interface block 26 has a built-in transport device A8 (transport unit) including a delivery arm. The transport device A8 delivers the workpiece W disposed in the shelf unit U11 to the exposure device 30. The transport device A8 receives the workpiece W from the exposure device 30 and returns the workpiece W back to the shelf unit U1.

The control device 100 (control unit) controls the units configuring each block such that a target resist pattern is formed in the workpiece W. For example, the control device 100 controls the exposure unit (for example, the processing unit U1 in the processing module) such that the entire region including the part irradiated with the first radiation and other parts in the resist film is irradiated with the second radiation in a batch. In addition, the control device 100 can also control the transport unit (transport device A8) of the interface block 26 such that the workpiece having the resist film irradiated with the first radiation is transported to the exposure unit in the exposure device 30.

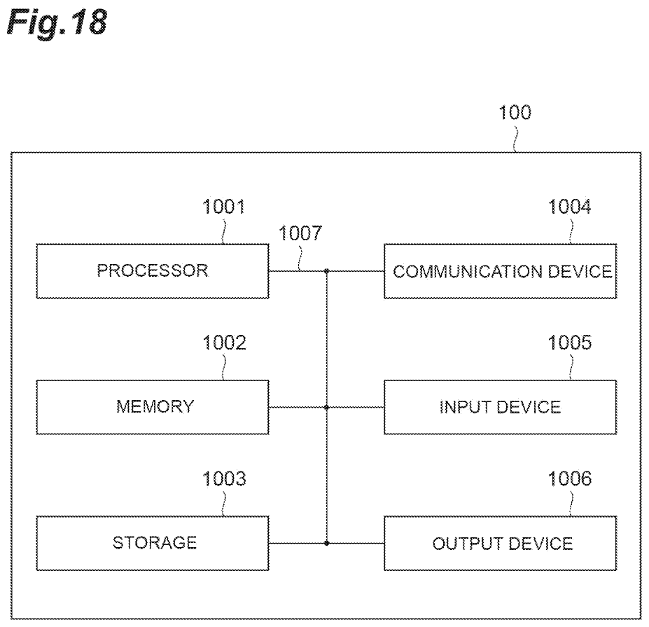

For example, the control device 100 according to an embodiment of the present disclosure may function as a computer that performs each process in the method for forming a resist pattern of the present disclosure. FIG. 18 is a view illustrating an example of the hardware configuration of the control device 100. Physically, the control device 100 is configured as a computer device including a processor 1001, a memory 1002, a storage 1003, a communication device 1004, an input device 1005, an output device 1006, a bus 1007, and the like.

In a case where a predetermined software (program) is loaded on a hardware such as the processor 1001 and the memory 1002, the processor 1001 performs arithmetic operations to control the communication by the communication device 1004 or control at least either reading or writing of data in the memory 1002 and the storage 1003, which enables the functions of the control device 100 to be executed.

The processor 1001 controls the entire computer by operating, for example, an operating system. The processor 1001 may be configured with a Central Processing Unit (CPU) including an interface with a peripheral device, a control device, an arithmetic unit, a register, and the like. For example, the control device 100 may control the exposure unit by the processor 1001.

The processor 1001 reads a program (program code), a software module, data and the like from at least either the storage 1003 or the communication device 1004 to the memory 1002, and executes various processes according to the program, the software module, the data, and the like. As the program, a program is used which causes a computer to execute at least a part of the operation described in the above embodiment. For example, the control device 100 may be realized by a control program that is stored in the memory 1002 and operated in the processor 1001. Other functional blocks may be realized in the same way. The above various processes are described as being executed by one processor 1001. However, the processes may be simultaneously or sequentially executed by two or more processors 1001. The processor 1001 may be mounted as a computer-readable storage medium that stores a program for causing a device to execute the method for forming a resist pattern according to an embodiment of the present disclosure. The processor 1001 may be mounted by one or more chips. The program may be transmitted from a network through a telecommunication circuit.

The memory 1002 is a computer-readable recording medium, and may be configured, for example, with at least one of a Read Only Memory (ROM), an Erasable Programmable ROM (EPROM), an Electrically Erasable Programmable ROM (EEPROM), a Random Access Memory (RAM), and the like. The memory 1002 may be called a register, a cache, a main memory (main storage unit), or the like. The memory 1002 can store a program (program code), a software module, and the like for performing the method for forming a resist pattern according to an embodiment of the present disclosure.

The storage 1003 is a computer-readable recording medium, and may be configured, for example, with at least one of an optical disk such as a Compact Disc ROM (CD-ROM), a hard disk drive, a flexible disk, a magneto-optical disk (for example, a compact disk, a digital versatile disk, or a Blu-ray (Registered trademark) disk), a smart card, a flash memory, a floppy (registered trademark) disk, a magnetic strip, and the like. The storage 1003 may be called an auxiliary storage unit.

The communication device 1004 is hardware (transceiver) for performing communication between computers through at least either a wired network or a wireless network, and is also called, for example, a network device, a network controller, a network card, a communication module, or the like.

The input device 1005 is an input device (for example, a keyboard, a microphone, a switch, a button, a sensor, or the like) that receives an input from the outside. The output device 1006 is an output device (for example, a display, a speaker, an LED lamp, or the like) that performs output to the outside. Note that the input device 1005 and the output device 1006 may have an integrated configuration (for example, a touch panel).

Each device, such as the processor 1001 or the memory 1002, is connected by the bus 1007 for communicating information. The bus 1007 may be configured with a single bus, or may be configured with different buses for the respective devices.

The control device 100 may be configured to include hardware such as a microprocessor, a Digital Signal Processor (DSP), an Application Specific Integrated Circuit (ASIC), a Programmable Logic Device (PLD), or a Field Programmable Gate Array (FPGA). Some or all of the functional blocks may be realized by the hardware. For example, the processor 1001 may be mounted using at least one of the hardwares.

The control device 100 may have a storage that stores a program for executing the method described above. The storage includes, for example, a computer-readable storage medium that stores a program and a device that reads data from the storage medium. The storage medium is a non-volatile medium, and examples thereof include a hard disk and a Read Only Memory (ROM).

The specific configuration of the substrate processing device is not limited to the configuration of the substrate processing device 20 illustrated above. For example, an exposure unit that radiates the second radiation to the resist film having the part irradiated with the first radiation may be provided between the processing block and the interface block.

The present invention is not limited to the following verification examples.

### VERIFICATION EXAMPLE 1

### 1.1. Photoresist Composition

As resist materials, a cage-shaped tin oxide compound and nanoparticles having an organic ligand ([SnR)₁₂O₁₄(OH)₆]OH)₂, and R is an alkyl group, sometimes called “MOR” hereinafter) were prepared. An MOR solution having a concentration of 0.01 M was prepared as a photoresist composition 1.

### 1-2. Pattern formation test

### COMPARATIVE EXAMPLE 1

An SOC film formed on a silicon wafer was coated with the photoresist composition 1 by using a spin coater. The coating film was heated at 100° C. for 60 seconds to remove the solvent, thereby forming a resist film having a thickness of 22 nm. Through a mask having a pattern corresponding to a line/space with a half pitch of 32 nm, the resist film was exposed to extreme ultraviolet rays (EUV) having a wavelength of 13.5 nm. The EUV dose was 69.5 L/cm³. After the exposure, the resist film was baked by heating at 180° C. for 60 seconds. The baked resist film was subjected to a development process using propylene glycol monomethyl ether acetate (PGMEA) containing acetic acid. After the development process, the formed linear resist pattern was observed with a scanning electron microscope to measure the critical dimension (CD) and the line edge roughness (LER) of the resist pattern.

### EXAMPLE 1-1

An SOC film formed on a silicon wafer was coated with the photoresist composition 1 by using a spin coater. The coating film was heated at 100° C. for 60 seconds to remove the solvent, thereby forming a resist film having a thickness of 22 nm. Through a mask having a pattern corresponding to a line/space with a half pitch of 32 nm, the resist film was exposed to extreme ultraviolet rays (EUV) having a wavelength of 13.5 nm. After the exposure, the resist film was baked by heating at 180° C. for 60 seconds. The entire surface of the baked resist film was exposed to a KrF excimer laser. The EUV dose was 65.5 J/cm², and the dose of the KrF excimer laser was 10 mJ/cm 2. The resist film having been exposed to the KrF excimer laser was subjected to a development process using propylene glycol monomethyl ether acetate (PGMEA) containing acetic acid. After the development process, the formed linear resist pattern was observed with a scanning electron microscope to measure the critical dimension (CD) and the line edge roughness (LER) of the resist pattern.

### EXAMPLE 1-2

A resist pattern was formed in the same manner as in Example 1-1, except that the EUV dose was changed to 61.5 J/cm² and the dose of the KrF excimer laser was changed to 20 mJ/cm². The critical dimension (CD) and line edge roughness (LER) of the resist pattern were measured.

TABLE 1

| | Comp. Ex. 1 | Ex. 1-1 | Ex. 1-2 |
|---|---|---|---|
| Dose of EUV pattern | 69.5 | 65.5 | 61.5 |
| exposure [mJ/cm²] | | | |
| Baking after pattern | 180° C., | 180° C., | 180° C., |
| exposure | 30 sec | 30 sec | 30 sec |
| Dose of KrF batch | 0 | 10 | 20 |
| exposure [mJ/cm²] | | | |
| D [nm] | 16.65 | 16.57 | 16.6 |
| LWR [nm] | 3.67 | 3.56 | 3.63 |

From the evaluation results shown in Table 1, it has been confirmed that the combination of the baking after pattern exposure and the batch exposure after baking reduces the roughness of the resist pattern.

### VERIFICATION EXAMPLE 2

### 2-1. Photoresist Composition

A photoresist composition 2 was prepared which contained a polymer component that becomes soluble in a developer solution by the action of an acid and a photoacid generator (PAG) that is a sulfonium salt having a cation represented by the following formula. The sulfonium salt having a cation represented by the following formula also functions as a sensitizer precursor component.

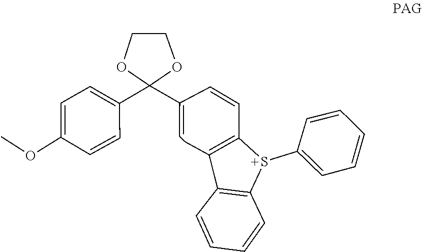

### 2-2. Pattern Formation Test

### COMPARATIVE EXAMPLE 2

An SOC film formed on a silicon wafer was coated with the photoresist composition 2 by using a spin coater. The coating film was heated at 130° C. for 60 seconds to remove the solvent, thereby forming a resist film having a thickness of 50 nm. Through a mask having a pattern with annular openings having a width of 150 nm, the resist film was exposed to a KrF excimer laser. The dose of the radiated KrF excimer laser was 10 to 200 mJ/cm² (45.9 J/cm²). After the exposure, the resist film was baked by heating at 110° C. for 60 seconds. The baked resist film was subjected to a development process using an aqueous tetramethylammonium hydroxide solution. After the development process, the formed resist pattern was observed with a scanning electron microscope to measure the line width roughness (LWR) of the resist pattern.

### EXAMPLE 2-1

An SOC film formed on a silicon wafer was coated with the photoresist composition 2 by using a spin coater. The coating film was heated at 130° C. for 60 seconds to remove the solvent, thereby forming a resist film having a thickness of 50 nm. Through a mask having a pattern with annular openings having a width of 150 nm, the resist film was exposed to a KrF excimer laser. The dose of the radiated KrF excimer laser was 10 to 200 mJ/cm² (41.4 J/cm²). After the exposure, the resist film was baked by heating at 110° C. for 60 seconds. The entire surface of the baked resist film was exposed to 395 nm UV. The UV dose was 5 J/m². The resist film having undergone UV exposure was subjected to a development process using an aqueous tetramethylammonium hydroxide solution. After the development process, the formed resist pattern was observed with a scanning electron microscope to measure the line width roughness (LWR) of the resist pattern.

### EXAMPLE 2-2

A resist pattern was formed in the same manner as in Example 2-1, except that the dose of the KrF excimer laser was changed to 39.8 mJ/cm² and the UV dose was changed to 10 J/m². The line width roughness (LWR) of the resist pattern was measured.

### EXAMPLE 2-3

A resist pattern was formed in the same manner as in Example 2-1, except that the dose of the KrF excimer laser was changed to 39.1 mJ/cm² and the UV dose was changed to 15 J/m². The line width roughness (LWR) of the resist pattern was measured.

TABLE 2

| | Comp. Ex. 2 | Ex. 2-1 | Ex. 2-2 | Ex. 2-3 |
|---|---|---|---|---|
| Dose of KrF | 45.9 | 41.4 | 39.8 | 39.1 |
| pattern exposure | | | | |
| [mJ/cm²] | | | | |
| Baking after | 110° C., | 110° C., | 110° C., | 110° C., |
| pattern exposure | 60 sec | 60 sec | 60 sec | 60 sec |
| Dose of UV batch | 0 | 5 | 10 | 15 |
| exposure [J/cm²] | | | | |
| LWR [nm] | 16.0 | 15.5 | 15.7 | 15.6 |

From the evaluation results shown in Table 2, it has been confirmed that the combination of the baking after pattern exposure and the batch exposure after baking reduces the roughness of the resist pattern.

### VERIFICATION EXAMPLE 3

### 3-1. Photoresist Composition

In the following tests, the same photoresist composition 1 as the photoresist composition 1 of Verification Example 1 was used.

### 3-1. Underlayer Film of Resist

The entire surface of a silicon wafer was coated with a coating liquid for forming an underlayer film containing polycarbosilane including a constitutional unit having a silicon atom and a hydrocarbon group bonded to the silicon atom, and the coating film was heated, thereby forming an underlayer film containing a silicon-containing material that contains silicon atoms and carbon atoms.

### 3-2. Verification Test

### Test 1

By using a spin coater, the underlayer film formed on the silicon wafer was coated with the photoresist composition 1. The coating film was heated at 100° C. for 60 seconds to remove the solvent, thereby forming a resist film having a thickness of about 15 nm. The resist film was exposed to extreme ultraviolet rays (EUV) having a wavelength of 13.5 nm. A plurality of regions was exposed in a state where the exposure amount was being sequentially changed from 0 mJ/cm²(no exposure) to 46 mJ/cm². In this way, a plurality of resist films including regions irradiated with EUV at different doses was prepared. The exposed resist film was baked by heating at 180° C. for 60 seconds. The entire surface of the baked resist film was exposed to a KrF excimer laser (wavelength: 248 nm) in a batch. Each of the plurality of resist films was exposed to the KrF excimer laser at doses of 0 mJ/cm² (no exposure), 10 mJ/m², 20 mJ/m², or 30 mJ/m². The resist films having been subjected to batch exposure with the KrF excimer laser were subjected to a development process using a developer solution (PGMEA/AA) containing propylene glycol monomethyl ether acetate and acetic acid. The thickness of the resist film remaining after the development process was measured.

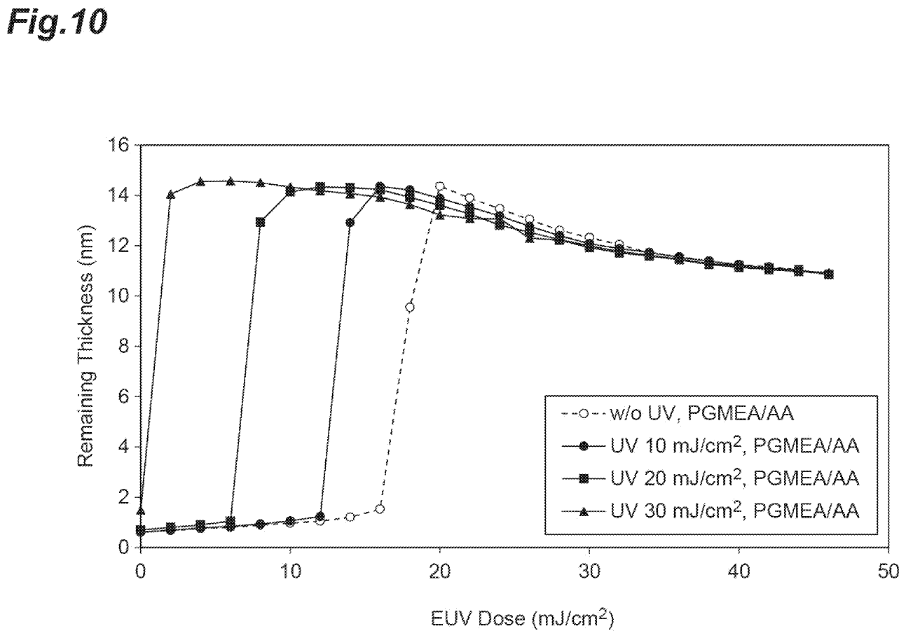

FIG. 10 is a graph illustrating a relationship between the thickness of a resist film remaining after a development process and EUV dose. It has been confirmed that the thickness of the remaining resist film tends to change with higher contrast relative to the EUV dose due to the ultraviolet exposure after the EUV exposure.

### Test 2

By using a spin coater, the underlayer film formed on the silicon wafer was coated with the photoresist composition 1. The coating film was heated at 100° C. for 60 seconds to remove the solvent, thereby forming a resist film having a thickness of about 15 nm. The resist film was exposed to a KrF excimer laser. A plurality of regions was exposed in a state where the dose was being sequentially changed from 0 J/cm² (no exposure) to 46 J/cm². In this way, a plurality of resist films including regions irradiated with EUV at different doses was prepared. The exposed resist film was baked by heating at 180° C. for 60 seconds. The entire surface of the baked resist film was exposed to a KrF excimer laser (wavelength: 248 nm) in a batch. Each of the plurality of resist films was exposed in a batch to the KrF excimer laser at doses of 0 mJ/cm² (no exposure) or 10 mJ/cm². The resist film having undergone batch exposure with the KrF excimer laser was subjected to a development process using an aqueous tetramethylammonium hydroxide solution (TMAH). The thickness of the resist film remaining after the development process was measured.

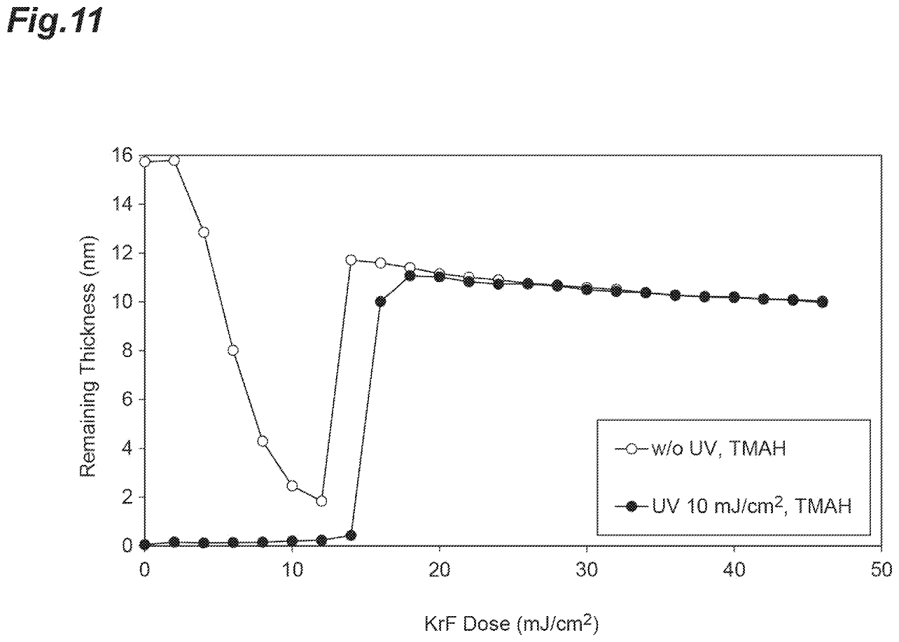

FIG. 11 is a graph illustrating a relationship between the thickness of a resist film remaining after a development process and dose of the first KrF excimer laser. It has been confirmed that the thickness of the resist film changes with high contrast relative to the dose by the ultraviolet batch exposure after the exposure to the KrF excimer laser. Furthermore, it has been confirmed that the amount of residues in the region exposed to the KrF excimer laser at a low dose tends to be further reduced compared to the case where PGEMA/AA is used as a developer solution. It is considered that in the case of pattern exposure by EUV, the contrast relative to the dose may tend to increase as well.

### Test 3

By using a spin coater, the underlayer film formed on the silicon wafer was coated with the photoresist composition 1. The coating film was heated at 100° C. for 60 seconds to remove the solvent, thereby forming a resist film having a thickness of about 15 nm. The resist film was exposed to EUV. A plurality of regions was exposed in a state where the dose was being sequentially changed from 0 J/m² (no exposure) to 46 J/m². In this way, a plurality of resist films including regions irradiated with EUV at different doses was prepared. The exposed resist film was baked by heating at 200° C. for 60 seconds. The entire surface of the baked resist film was subjected to batch exposure with a KrF excimer laser (wavelength: 248 nm) or a Xe excimer laser (wavelength: 172 nm). The resist film having undergone batch exposure with the KrF excimer laser or the Xe excimer laser was subjected to a development process using an aqueous tetramethylammonium hydroxide solution (TMAH). The thickness of the resist film remaining after the development process was measured with a thickness measurement system (KLA Tencor Aleris).

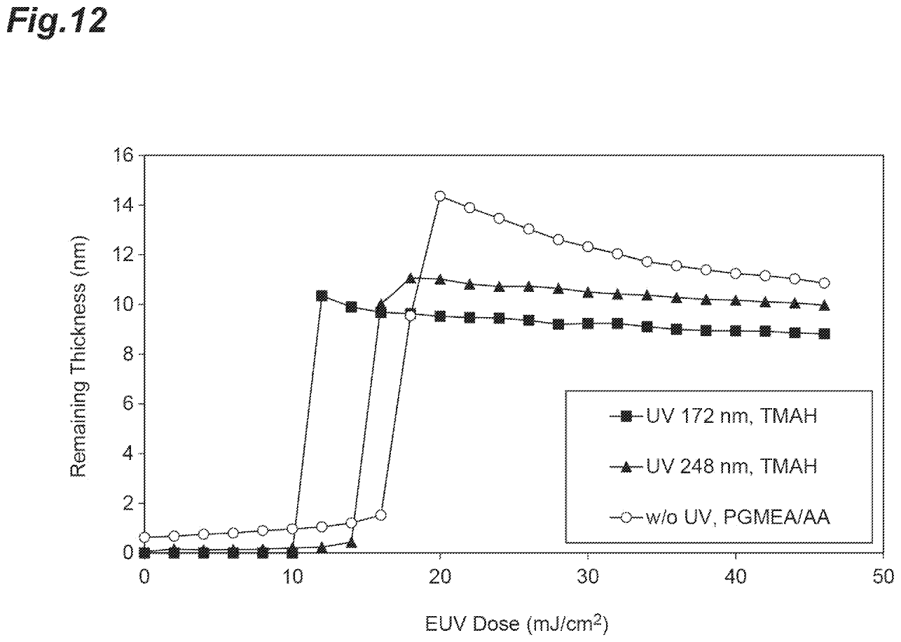

FIG. 12 is a graph illustrating a relationship between the thickness of a resist film remaining after a development process and EUV dose. For comparison, the results obtained in a case where batch exposure with a KrF excimer laser is not performed in Test 1 are also shown in FIG. 12. It has been confirmed that in a case where the ultraviolet wavelength is 172 nm, the thickness of the remaining resist film also tends to change with high contrast relative to the EUV dose due to the batch exposure to ultraviolet rays after the EUV exposure.

### Test 4

By using a spin coater, the underlayer film formed on the silicon wafer was coated with the photoresist composition 1. The coating film was heated at 160° C. for 60 seconds to remove the solvent, thereby forming a resist film having a thickness of 22 nm. Through a mask having a pattern corresponding to line/space with a half pitch of 16 nm, the resist film was exposed to EUV. A plurality of resist films irradiated with EUV at different doses was prepared. After the exposure, the resist film was baked by heating at 200° C. for 60 seconds. The entire surface of the baked resist film was subjected to batch exposure with a KrF excimer laser. The dose of the KrF excimer laser was 70 mJ/cm². The resist film having undergone batch exposure by the KrF excimer laser was subjected to a development process using TMAH.

The resist film having undergone the same EUV exposure as described above was baked by heating at 180° C. for 60 seconds without being subjected to batch exposure with a KrF excimer laser. The baked resist film was subjected to a development process using TMAH.

After the development process, the formed linear resist pattern was observed with a scanning electron microscope to measure the critical dimension (CD), line width roughness (LWR), and number of defects (number of parts where the resist film was missing) of the resist pattern.

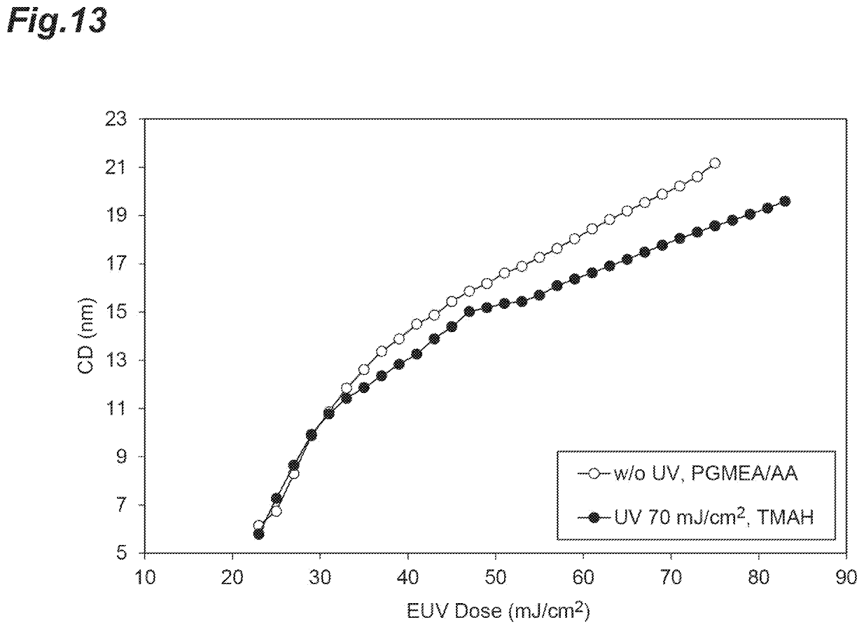

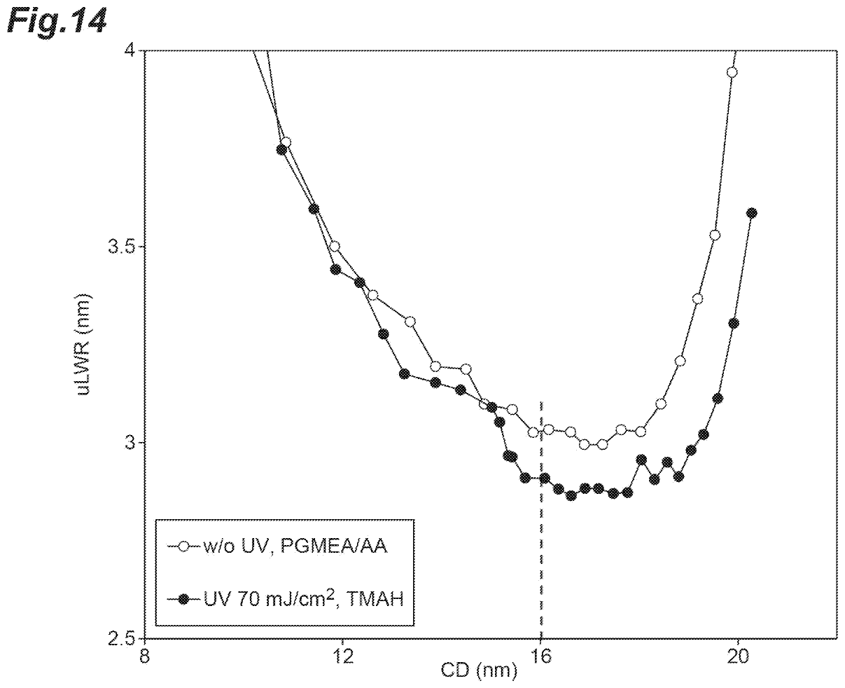

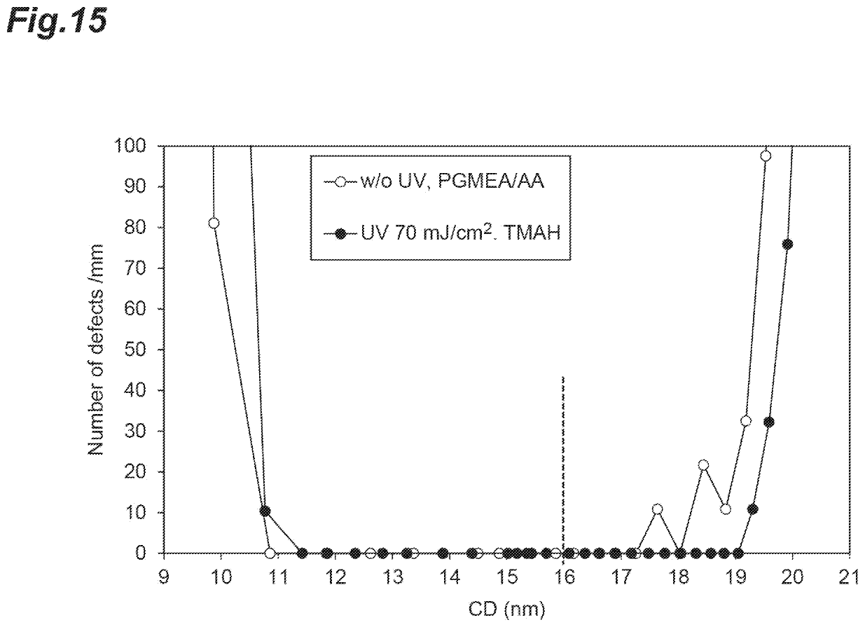

FIG. 13 is a graph showing the relationship between CD and EUV dose, FIG. 14 is a graph showing the relationship between LWR and CD, and FIG. 15 is a graph showing the relationship between the number of defects and CD. From these results, it has been confirmed that the batch exposure to ultraviolet rays after the EUV exposure improves the margins for EUV exposure relating to CD, LWR, and the number of defects.

### Test 5

By using a spin coater, the underlayer film formed on the silicon wafer was coated with the photoresist composition 1. The coating film was heated at 100° C. for 60 seconds to remove the solvent, thereby forming a resist film having a thickness of 22 nm. Through a mask having a pattern corresponding to a plurality of pillars arranged at an interval of 36 nm, the resist film was exposed to EUV. A plurality of resist films irradiated with EUV at different doses was prepared. After the exposure, the resist film was baked by heating at 160° C. for 60 seconds. The entire surface of the baked resist film was subjected to batch exposure with a KrF excimer laser. The dose of the KrF excimer laser was 50 mJ/cm². The resist film having undergone batch exposure by the KrF excimer laser was subjected to a development process using deionized water (DIW).

The resist film having undergone the same EUV exposure as described above was baked by heating at 160° C. for 60 seconds without being subjected to batch exposure with a KrF excimer laser. The baked resist film was subjected to a development process using deionized water.

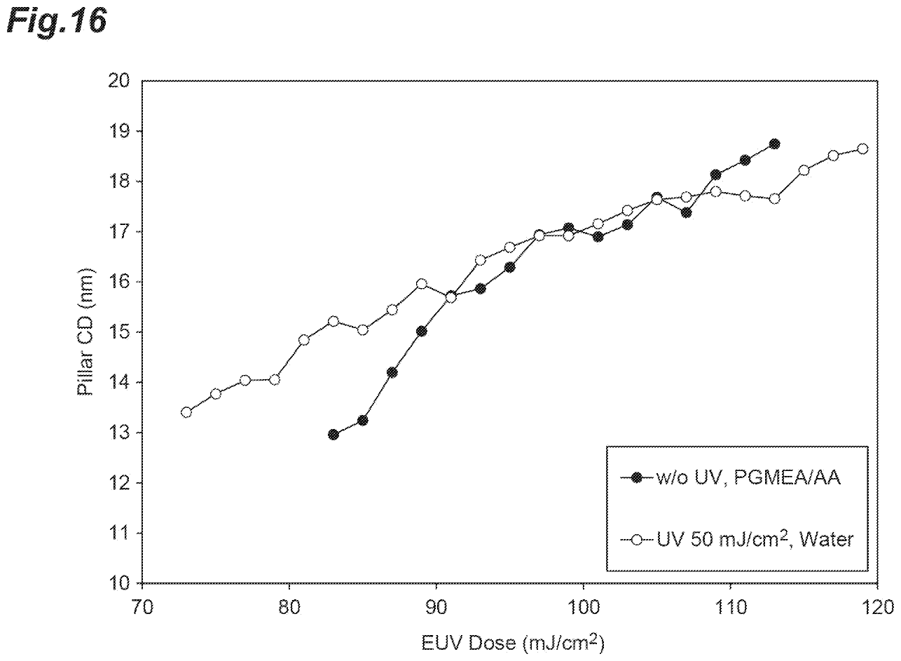

After the development process, the formed linear resist pattern was observed with a scanning electron microscope to measure the width (CD) of the formed pillars. FIG. 16 is a graph showing the relationship between CD and EUV dose. It has been confirmed that even though deionized water is used as a developer solution, it is possible to form a pattern by development while maintaining a high margin for EUV exposure.

### Test Example 6

By using a spin coater, the underlayer film formed on the silicon wafer was coated with the photoresist composition 1. The coating film was heated at 100° C. for 60 seconds to remove the solvent, thereby forming a resist film having a thickness of 22 nm. The resist film was exposed to a KrF excimer laser. A plurality of regions was exposed in a state where the radiation dose was being sequentially changed from 0 J/m² (no exposure) to 46 J/m². In this way, a plurality of resist films including regions irradiated with the KrF excimer laser at different doses was prepared. After the exposure, the resist film was baked by heating at 210° C. for 60 seconds. The entire surface of the baked resist film was subjected to batch exposure with ultraviolet having a wavelength of 280 nm. The resist film having undergone batch exposure was subjected to a development process using TMAH. The resist film (resist pattern) having undergone the development process was baked by heating at 250° C. for 60 seconds. The thickness of the resist film (with PDB) remaining after baking was measured. After the development process, the thickness of the unbaked resist film (w/o PDB) was measured as well.

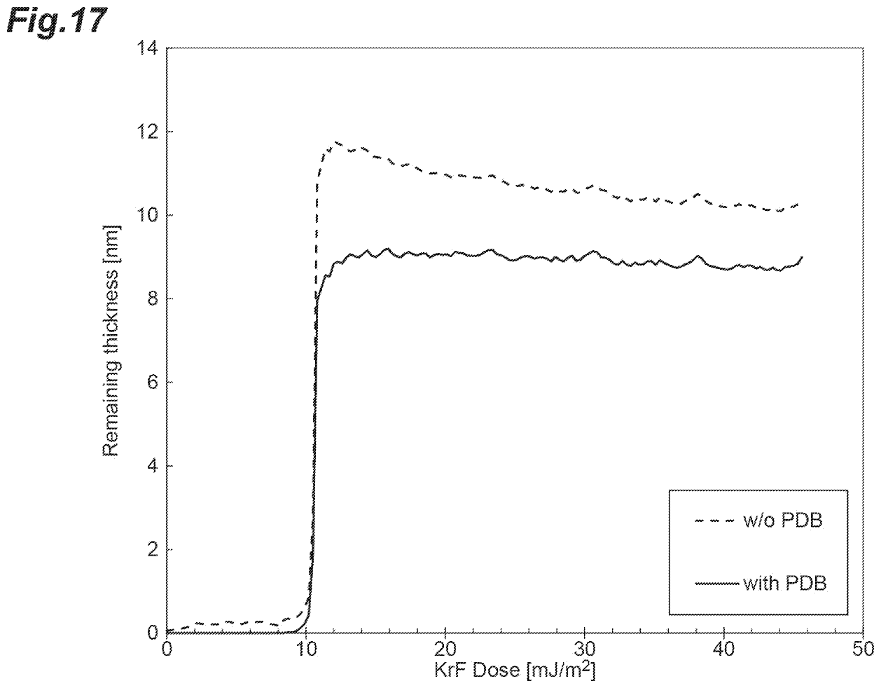

FIG. 17 is a graph illustrating a relationship between the thickness of a resist film remaining after a development process and dose of a KrF excimer laser. It has been confirmed that the post-baking after the development process further reduces the resist film remaining in the region subjected to pattern exposure with a KrF excimer laser at a low dose. It is considered that in the case of pattern exposure by EUV, the remaining resist film may tend to be reduced as well.

The present disclosure includes at least the following aspects.

[1]

A method for forming a resist pattern, comprising, in the following order:

irradiating a part of a resist film containing a resist material with a first radiation;

baking the resist film;

irradiating an entire region including the part irradiated with the first radiation and other parts in the resist film with a second radiation in a batch; and

forming a resist pattern by development for removing a part of the resist film,

wherein the first radiation is ionizing radiation or non-ionizing radiation,

wherein the second radiation is non-ionizing radiation, and

wherein in a case where the first radiation is non-ionizing radiation, the second radiation is non-ionizing radiation having a wavelength longer than a wavelength of the first radiation.

[2]

The method according to [1],

wherein the resist material is a metal oxide photoresist material.

[3]

The method according to [1] or [2],

wherein the resist material is a chemically amplified photoresist material containing a polymer component that becomes soluble or insoluble in a developer solution by action of an acid and an acid generator that generates an acid by the first radiation,

wherein the resist material further contains a sensitizer precursor component as one or more components selected from the polymer component, the acid generator, and a component different from the polymer component and the acid generator, and

wherein the sensitizer precursor component enhances absorption of the second radiation into the resist material by the action of an acid.

[4]

The method according to any one of [1] to [3],

wherein the second radiation is ultraviolet rays having a wavelength of 100 nm or more.

[5]

The method according to any one of [1] to [4], further comprising:

irradiating the resist pattern formed by the development with ultraviolet rays.

[6]

The method according to any one of [1] to [5], further comprising:

baking the resist pattern formed by the development.

[7]

A method for forming a resist pattern, comprising, in the following order:

irradiating a part of a resist film containing a resist material with a first radiation;

baking the resist film;

irradiating an entire region including the part irradiated with the first radiation and other parts in the resist film with a second radiation in a batch; and

forming a resist pattern by development for removing a part of the resist film,

wherein the first radiation is extreme ultraviolet rays,

wherein the second radiation is ultraviolet rays having a wavelength of 100 nm or more, and

wherein the resist film contains a metal oxide photoresist material.

[8]

The method according to [7],

wherein the metal oxide photoresist material can contain a metal oxide containing a metal atom and an organic ligand bonded to the metal atom, and

wherein the irradiation of the resist film with the second radiation results in formation of a metal hydroxide from the metal oxide in a part not being irradiated with the first radiation in the resist film, leading to reduction of roughness of the resist pattern.

[9]

The method according to [7],

wherein the resist film is not irradiated with the second radiation before irradiated with the first radiation.

[10]

The method according to any one of [7] to [9], further comprising:

baking the resist pattern formed by the development.

[11]

The method according to any one of [7] to

wherein a part of the resist film formed on an underlayer film is irradiated with the first radiation, and

wherein the underlayer film is a film containing a silicon-containing material that contains a silicon atom and a carbon atom bonded to the silicon atom.

[12]

The method according to [11],

wherein the underlayer film is a film formed by heating a film of a composition containing polycarbosilane having an organic group bonded to the silicon atom.

[13]

The method according to [11],

wherein the underlayer film is a film formed by heating a film of a composition containing polysiloxane having an organic group bonded to the silicon atom.

[14]

The method according to any one of [7] to [13],

wherein the development is wet development including bringing the resist film into contact with a developer solution, and

wherein the developer solution is an aqueous tetramethylammonium hydroxide solution or water.

[15]

The method according to any one of [7] to [13],

wherein the development is dry development including exposing the resist film to a developer gas.

[16]

The method according to [15],

wherein the developer gas is an acidic gas.

[17]

A method for producing a semiconductor device having a patterned film, the method comprising:

forming a resist pattern on an underlayer film (an etching target film) by the method according to any one of [1] to [16], the resist pattern having a trench in which the underlayer film (the etching target film) is exposed, and

etching the underlayer film (the etching target film) exposed in the trench such that the underlayer film (the etching target film) is patterned.

[18]

A substrate processing device, comprising:

an irradiator that irradiates a resist film having a part irradiated with a first radiation with a second radiation;

a developer that forms a resist pattern by development for removing a part of the resist film; and

a circuit that is configured to control the irradiator such that an entire region including the part irradiated with the first radiation and other parts in the resist film is irradiated with the second radiation in a batch,

wherein the first radiation is ionizing radiation or non-ionizing radiation,

wherein the second radiation is non-ionizing radiation, and

wherein in a case where the first radiation is non-ionizing radiation, the second radiation is non-ionizing radiation having a wavelength longer than a wavelength of the first radiation.

[19]

The substrate processing device according to [18], further comprising:

a heater that bakes the resist film formed on a workpiece having an underlayer film.

[20]

A computer-readable storage medium that stores a program for causing a device to execute the method according to any one of [1] to [16].

### REFERENCE SIGNS LIST

1: semiconductor wafer

3: underlayer film (etching target film)

3A: patterned underlayer film (etching target film)

3a, 5a; trench

5: resist film

5A: resist pattern

5E: part of resist film irradiated with first radiation

7: mask

R1: first radiation

R2: second radiation

11,12,13,14: processing module

20: substrate processing device

25 24: carrier block

25: processing block

26 interface block

30: exposure device

40: exposure unit

41: case

42: transportation port

50: moving mechanism portion

51: support

52: support stand

53: rotary portion

54: mounting platform

60: light source module

61: case

62: light source

63: shutter

64: shutter-moving mechanism portion

100: control device

C: carrier

W: workpiece

U1 U2: processing unit

1. A method for forming a resist pattern, comprising, in the following order:
irradiating a part of a resist film comprising a resist material with a first radiation;
baking the resist film;
irradiating an entire region including the part irradiated with the first radiation and other parts in the resist film with a second radiation in a batch; and
forming a resist pattern by development for removing a part of the resist film,
wherein the first radiation is ionizing radiation or non-ionizing radiation,
wherein the second radiation is non-ionizing radiation, and
wherein in a case where the first radiation is non-ionizing radiation, the second radiation is non-ionizing radiation having a wavelength longer than a wavelength of the first radiation.

2. The method according to claim 1,
wherein the resist material is a metal oxide photoresist material.

3. The method according to claim 1,
wherein the resist material is a chemically amplified photoresist material comprising a polymer component that becomes soluble or insoluble in a developer solution by action of an acid and an acid generator that generates an acid by the first radiation,
wherein the resist material further comprises a sensitizer precursor component as one or more components selected from the polymer component, the acid generator, and a component different from the polymer component and the acid generator, and
wherein the sensitizer precursor component enhances absorption of the second radiation into the resist material by the action of an acid.

4. The method according to claim 1,
wherein the second radiation is ultraviolet rays having a wavelength of 100 nm or more.

5. The method according to claim 1, further comprising:
irradiating the resist pattern formed by the development with ultraviolet rays.

6. The method according to claim 1, further comprising:
baking the resist pattern formed by the development.

7. A method for forming a resist pattern, comprising, in the following order:
irradiating a part of a resist film containing a resist material with a first radiation;
baking the resist film;
irradiating an entire region including the part irradiated with the first radiation and other parts in the resist film with a second radiation in a batch; and
forming a resist pattern by development for removing a part of the resist film,
wherein the first radiation is extreme ultraviolet rays,
wherein the second radiation is ultraviolet rays having a wavelength of 100 nm or more, and
wherein the resist film comprises a metal oxide photoresist material.

8. The method according to claim 7,
wherein the metal oxide photoresist material comprises an organic metal compound containing a metal oxide containing a metal atom and an organic ligand bonded to the metal atom, and
wherein the irradiation of the resist film with the second radiation results in formation of a metal hydroxide from the metal oxide in a part of the resist film not being irradiated with the first radiation, leading to reduction of roughness of the resist pattern.

9. The method according to claim 7,
wherein the resist film is not irradiated with the second radiation before radiated with the first radiation.

10. The method according to claim 7, further comprising:
baking the resist pattern formed by the development.

11. The method according to claim 7,
wherein a part of the resist film formed on an underlayer film is irradiated with the first radiation, and
wherein the underlayer film is a film comprising a silicon-containing material containing a silicon atom and a carbon atom bonded to the silicon atom.

12. The method according to claim 11,
wherein the underlayer film is a film formed by heating a film of a composition comprising polycarbosilane having an organic group bonded to the silicon atom.

13. The method according to claim 11,
wherein the underlayer film is a film formed by heating a film of a composition containing polysiloxane having an organic group bonded to the silicon atom.

14. The method according to claim 7,
wherein the development is wet development including bringing the resist film into contact with a developer solution, and
wherein the developer solution is an aqueous tetramethylammonium hydroxide solution or water.

15. The method according to claim 7,
wherein the development is dry development including exposing the resist film to a developer gas.

16. The method according to claim 15,
wherein the developer gas is an acidic gas.

17. A method for producing a semiconductor device having a patterned film, the method comprising:
forming a resist pattern on an underlayer film by the method according to claim 1, the resist pattern having a trench in which the underlayer film is exposed; and
etching the underlayer film exposed in the trench such that the underlayer film is patterned.

18. A substrate processing device comprising:
an irradiator that irradiates a resist film having a part irradiated with a first radiation with a second radiation;
a developer that forms a resist pattern by development for removing a part of the resist film; and
a circuit that is configured to control the irradiator such that an entire region including the part irradiated with the first radiation and other parts in the resist film is irradiated with the second radiation in a batch,
wherein the first radiation is ionizing radiation or non-ionizing radiation,
wherein the second radiation is non-ionizing radiation, and
wherein in a case where the first radiation is non-ionizing radiation, the second radiation is non-ionizing radiation having a wavelength longer than a wavelength of the first radiation.

19. The substrate processing device according to claim 18, further comprising:
a heater that bakes a resist film formed on a workpiece having an underlayer film.

20. A computer-readable storage medium that stores a program for causing a device to execute the method according to claim 1.
